(19) United States
(12) Patent Application Publication
(10) Pub. No.: US 2011/0120537 A1
(43) Pub. Date: May 26, 2011

(54) SILICON INKS FOR THIN FILM SOLAR CELL FORMATION, CORRESPONDING METHODS AND SOLAR CELL STRUCTURES

(76) Inventors: Goujun Liu, San Jose, CA (US); Clifford M. Morris, Pleasanton, CA (US); Igor Altman, Fremont, CA (US); Uma Srinivasan, Mountain View, CA (US); Shivkumar Chiruvolu, San Jose, CA (US)

(21) Appl. No.: 12/887,262

(22) Filed: Sep. 21, 2010

Related U.S. Application Data
(60) Provisional application No. 61/244,340, filed on Sep. 21, 2009.
(60) Provisional application No. 61/359,662, filed on Jun. 29, 2010.

(51) Int. Cl. H01L 31/0352; H01L 31/18

(52) U.S. Cl. 136/255; 438/87; 257/E31.032

(57) ABSTRACT

High quality silicon inks are used to form polycrystalline layers within thin film solar cells having a p-n junction. The particles deposited with the inks can be sintered to form the silicon film, which can be intrinsic films or doped films. The silicon inks can have a z-average secondary particle size of no more than about 250 nm as determined by dynamic light scattering on an ink sample diluted to 0.4 weight percent if initially having a greater concentration. In some embodiments, an intrinsic layer can be a composite of an amorphous silicon portion and a crystalline silicon portion.

### CROSS REFERENCE TO RELATED APPLICATIONS

This application claims priority to copending U.S. provisional patent application Ser. No. 61/244,340 filed on Sep. 21, 2009 to Liu et al., entitled “Si Ink for Photovoltaic,” and to copending U.S. provisional patent application Ser. No. 61/359,662 filed on Jun. 29, 2010 to Chiruvolu et al., entitled “Silicon/Germanium Nanoparticle Inks and Associated Methods,” both of which are incorporated herein by reference.

### FIELD OF THE INVENTION

The invention relates to solar cells formed with layers of semiconductor comprising polycrystalline silicon as a layer of the solar cell. The invention further relates to methods for the formation of solar cells with layers of polycrystalline silicon.

### BACKGROUND OF THE INVENTION

Photovoltaic cells operate through the absorption of light to form electron-hole pairs. A semiconductor material can be conveniently used to absorb the light with a resulting charge separation. The photocurrent is harvested at a voltage differential to perform useful work in an external circuit, either directly or following storage with an appropriate energy storage device.

Various technologies are available for the formation of photovoltaic cells, e.g., solar cells, in which a semiconducting material functions as a photoconductor. A majority of commercial photovoltaic cells are based on silicon. With non-renewable energy sources continuing to be less desirable due to environmental and cost concerns, there is continuing interest in alternative energy sources, especially renewable energy sources. Increased commercialization of renewable energy sources relies on increasing cost effectiveness through lower costs per energy unit, which can be achieved through improved efficiency of the energy source and/or through cost reduction for materials and processing. Solar cells based on single crystal silicon are designed based on a relatively small optical absorption coefficient relative to polycrystalline silicon or amorphous silicon. Based on the larger optical absorption coefficient polycrystalline silicon or amorphous silicon. Based on the larger optical absorption coefficient for polycrystalline silicon and amorphous silicon, these materials have been formed into thin film solar cells.

### SUMMARY OF THE INVENTION

In a first aspect, the invention pertains to a method for forming a thin film solar cell structure comprising depositing a layer of ink comprising elemental silicon particles and sintering the elemental silicon particles to form a polycrystalline layer as an element of a p-n junction diode structure. The silicon ink can have a z-average secondary particle size of no more than about 250 nm as determined by dynamic light scattering on an ink sample diluted to 0.4 weight percent if initially having a greater concentration. The overall the structure comprises a p-doped elemental silicon layer and an n-doped elemental silicon layer forming the p-n junction.

In a further aspect, the invention pertains to a thin film solar cell comprising a composite layer having a composite of polycrystalline silicon and amorphous silicon with a textured interface between domains of the polycrystalline silicon and amorphous silicon that on average form adjacent layers. The overall structure comprises a p-doped elemental silicon layer and an n-doped elemental silicon layer form a diode junction. The texture can reflect the crystallite size of the polycrystalline material

### BRIEF DESCRIPTION OF THE DRAWINGS

FIG. 1 is a schematic sectional view of a thin film solar cell design with a photovoltaic element adjacent transparent conductive electrodes and supported with a transparent front layer.

FIG. 2 is a schematic sectional view of an embodiment of a thin film solar cell comprising a p-n junction with polycrystalline p-doped silicon layer and n-doped silicon layer in which at least one of the doped silicon layers is formed using a silicon ink that is sintered following deposition.

FIG. 3 is a schematic sectional view of a thin film solar cell comprising a p-i-n junction where the i-layer comprises intrinsic elemental silicon that is polycrystalline or amorphous.

FIG. 4 is a schematic sectional view of a thin film solar cell where the intrinsic layer comprises a polycrystalline component formed using a silicon ink and an amorphous silicon component.

FIG. 5 is a schematic sectional view of an embodiment of a thin film solar cell comprising two photovoltaic elements.

FIG. 6 is a schematic perspective view of a system for performing ink deposition and laser sintering.

FIG. 7 is a plot of the distribution of scattering intensity as a function of secondary particle size of nanoparticles dispersed in isopropyl alcohol wherein the average primary particle size is 25 nm.

FIG. 8 is a plot of the distribution of scattering intensity as a function of secondary particle size of nanoparticles dispersed in isopropyl alcohol wherein the average primary particle size is 9 mm.

FIG. 9 is a plot of the distribution of scattering intensity as a function of secondary particle size of nanoparticles dispersed in ethylene glycol.

FIG. 10 is a plot of the distribution of scattering intensity as a function of secondary particle size of nanoparticles dispersed in terpineol.

FIG. 11 is a plot of viscosity as a function of shear rate for a non-Newtonian Si nano-particle paste.

FIG. 12 is a scanning electron micrograph (SEM) image of a cross-section of a polycrystalline silicon thin-film layer formed from an ink that was deposited with spin coating and sintered with an excimer laser.

FIG. 13 is a SEM image of a cross-section of a polycrystalline silicon thin-film layer of FIG. 11 after treatment with an isopropyl alcohol solution.

FIG. 14 is a transmission electron micrograph (TEM) image of a cross-section of a single crystallite in the film.

FIG. 15A is a composite image comprising an electron micrograph image of a cross-section of a single crystal particle and electron diffraction patterns from the bulk particle.

FIG. 15B is a composite image comprising an electron micrograph image of a cross-section of a single crystal particle and electron diffraction patterns from the edge regions of the particle.

FIG. 16 is a SEM image of a cross-section of the interface between two single crystallites in the film.

FIG. 17 is a SEM image of a cross section of a wafer with a polycrystalline silicon thin film with a deposited nanoparticle silicon ink over the polycrystalline thin film after a soft bake.

FIG. 18 is a SEM image of a cross section of an equivalent wafer shown in FIG. 17 after laser sintering the nanoparticle silicon ink to form additional polycrystalline silicon.

FIG. 19 is a SEM image of a cross section of a wafer coated with a transparent conductive oxide and a polycrystalline silicon layer on the transparent conductive oxide.

FIG. 20A is a SEM image of a cross section of a thin-film layer formed from laser sintering of an ink comprising silicon nanoparticles with an average primary particle size of 7 nm.

FIG. 20B is a SEM image of top surface of a thin-film layer formed from laser sintering of an ink comprising silicon nanoparticles with an average primary particle size of 35 nm under equivalent sintering conditions used to obtain the film in FIG. 20A.

FIG. 21A is a SEM image of the top surface of a laser sintered silicon thin-film layer wherein sintering comprised 1 laser pulse per laser spot.

FIG. 21B is a SEM image of the top surface of a laser sintered silicon thin-film layer wherein sintering comprised 20 laser pulses per laser spot.

FIG. 22A is a SEM image of the top surface of a laser sintered silicon thin-film layer sintered with a laser fluence of 70 mJ/cm².

FIG. 22B is a SEM image of the top surface of a laser sintered silicon thin-film layer sintered with a laser fluence of 117 mJ/cm².

FIG. 23A is a SEM image of the top surface of a laser sintered silicon thin-film layer sintered with a graded laser fluence.

FIG. 23B is a SEM image of the top surface of a laser sintered silicon thin-film layer sintered with a non-graded laser fluence.

FIG. 24 is a plot of sheet resistance as a function of laser fluence for thin-film silicon layer.

FIG. 25 is a plot of laser fluence threshold as a function of laser pulse duration.

FIG. 26 is a composite image of optical micrographs of thin-film layers with varying sheet resistances.

FIG. 27 is a plot of dopant concentration as a function of the depth in a thin-film silicon layer.

FIG. 28 is a plot of the minority carrier diffusion length as a function of sheet resistance for a thin silicon film formed form a silicon ink.

FIG. 29 is a schematic sectional view of a p-n junction structure.

FIG. 30 is a schematic diagram of a fafer surface with a plurality of p-n junctions formed at different locations using laser sintering an n-doped silicon ink at the selected locations along with resistance measurements for the corresponding locations on an actual processed wafer.

FIG. 31 is a SEM image of a cross section of an ink layer comprising nanoparticles with an average primary particle size of 7 nm.

FIG. 32 is a SEM image of a cross section of an ink layer comprising nanoparticles with an average primary particle size of 9 nm.

FIG. 33 is a SEM image of a cross section of an ink layer comprising nanoparticles with an average primary particle size of 25 nm.

FIG. 34 is an SEM image of a cross section of the ink layer as shown in FIG. 30 following thermal densification under Ar/H₂ gas.

FIG. 35 is an SEM image of a cross section of an ink layer as shown in FIG. 32 following densification under Ar/H₂ gas.

FIG. 36 is an SEM image of a cross section of an ink layer as shown in FIG. 30 following densification under Ar/H₂ gas and etching.

FIG. 37 is an SEM image of a cross section of an ink layer as shown in FIG. 32 following densification under Ar/H₂ gas and etching.

FIG. 38 is an SEM image of a cross section of an ink layer as shown in FIG. 30 following densification under N₂ gas.

FIG. 39 is an SEM image of a cross section of an ink layer as shown in FIG. 32 following densification under N₂ gas.

FIG. 40 is an SEM image of a cross section of an ink layer as shown in FIG. 30 following densification under N₂ gas and etching.

FIG. 41 is an SEM image of a cross section of an ink layer as shown in FIG. 32 following densification under N₂ gas and etching.

FIG. 42 is an SEM image of a cross section of an ink layer as shown in FIG. 30 following densification under compressed air.

FIG. 43 is an SEM image of a cross section of an ink layer as shown in FIG. 32 following densification under compressed air.

FIG. 44 is an SEM image of a cross section of an ink layer as shown in FIG. 30 following densification under compressed air and etching.

FIG. 45 is an SEM image of a cross section of an ink layer as shown in FIG. 32 following densification under compressed air and etching.

FIG. 46 is a plot of dopant concentration as a function of the depth in non-densified silicon ink layers.

FIG. 47 is a plot of dopant concentration as a function of the depth in densified silicon ink layers.

FIG. 48 is a plot of sheet resistance as a function of average primary particle size in densified silicon ink layers.

### DETAILED DESCRIPTION

Silicon inks can provide a significant precursor material for the formation of structures within a thin film solar cell. The silicon inks can be processed efficiently into polycrystalline, i.e., microcrystalline or nanocrystalline, films with reasonable electrical properties. High quality silicon inks have been developed based on corresponding high quality silicon nanoparticles. Thin film solar cells incorporate thin layers of amorphous and/or polycrystalline silicon within the active photocurrent generating structure. The solar cells of particular interest have a diode structure with layers of p-doped silicon and n-doped silicon. In some embodiments, the thin film solar cell structures incorporate an intrinsic layer, which is not doped or has a very low dopant level, between the p-doped and n-doped diode layers with the intrinsic layer being used to take a significant role in the absorption of light. The silicon inks can be formed with a range of dopant levels from non-doped to high dopant levels, for forming appropriate structures within a thin film solar cell. In some embodiments, the silicon ink can be formed by dispersing silicon nanoparticles formed by laser pyrolysis, which provides for the option of having relatively high dopant levels. The inks can be deposited using an appropriate technique, such as spin coating, spray coating or screen printing. After deposition for the formation of a solar cell element, the inks can be dried, and the silicon nanoparticles can be sintered into layer or film with a polycrystalline structure. The sintered inks can be naturally textured for desirable properties. The inks provide an efficient and cost effective tool for the formation of appropriate thin film solar cell structures.

Solar cells are generally formed with semiconductors that function as photoconductors that generate current upon the absorption of light. A range of semiconductor materials can be used for forming solar cells. However, for commercial applications, silicon has been the dominant semiconducting material. In general, crystalline silicon has been used effectively to form efficient solar cells. However, crystalline silicon has a lower absorption of visible light than amorphous silicon or polycrystalline silicon. Therefore, a greater amount of silicon material is used for forming the solar cell structures with crystalline silicon relative to amounts of silicon that can be used for solar cells based on amorphous or polycrystalline silicon. Since significantly smaller amounts of silicon are generally used, solar cells based on amorphous and/or polycrystalline silicon can be referred to as thin film solar cells.

In the thin film solar cells, absorption of light by the semiconductor results in the transfer of an electron from a valance band to a conduction band, and a diode junction creates an electric field in the structure that results in a net flow of current following absorption of light. In particular, doped layers of opposite polarity forming a diode p-n junction can be used for harvesting the photocurrent. To achieve improved harvesting of the photocurrent and a corresponding increase in photoelectric conversion efficiency, the doped layers extend across the light absorbing structure with adjacent electrodes as current collectors. The electrode on the light receiving side generally is a transparent conductive material, such as a conductive metal oxide, so that light can reach the semiconducting materials. The electrode contacting the semiconducting material on the back side of the cell can also be a transparent electrode with an adjacent reflective conductor, although on the back side optionally a reflective conductive electrode can be used directly on the semiconductor material without a transparent conductive oxide.

A layer of intrinsic, i.e., non-doped or very low doped silicon can be placed between the p-doped and n-doped layers. The intrinsic layer generally is formed with a greater average thickness to provide for absorbing desired amount of light. Design parameters for the cell generally balance absorption of light to increase the current and efficiency with respect to harvesting the current. The p-n junction generates an electric field that drives the current harvesting. Amorphous silicon has a high optical absorption coefficient for solar radiation relative to polycrystalline, and polycrystalline silicon has a correspondingly higher optical absorption coefficient than crystalline silicon. If an intrinsic layer is used, the overall structure then can be referred to as a p-i-n junction, where the letters refer to the p-doped, intrinsic and n-doped layers respectively. Generally, within a p-n junction the p-doped layer is placed toward the light receiving surface with the n-doped layer being further from the light receiving surface.

Amorphous silicon has a relatively large band gap of 1.7 eV, so that amorphous silicon generally does not efficiently absorb light with a wavelength of 700 nm or longer. Therefore, amorphous silicon may not effectively absorb a portion of the visible spectrum and correspondingly a significant portion of the solar radiation spectrum. In alternative or additional embodiments, one or more layers of the thin film solar cell comprise polycrystalline silicon. In other words, to overcome some of the deficiencies of forming a solar cell with only amorphous silicon, structures have been proposed that incorporate polycrystalline silicon. Thus, polycrystalline silicon can be use in addition or as a substitute for amorphous silicon. As described herein, the polycrystalline silicon layers can be formed using silicon inks that are deposited and sintered into the desired films.

Stacked cell have been developed in which separate stacks of absorbing semiconductors in p-n junctions are used to more fully exploit the incident light. Each p-n junction within the stack can have an intrinsic silicon absorbing layer to form a p-i-n junction. The p-n junctions within the stack are generally connected in series. In some embodiments, one or more p-i-n junctions are formed with amorphous silicon while one or more p-i-n junctions are formed with one or more layers of polycrystalline silicon. The p-i-n structure with amorphous silicon can be placed closer to the light receiving surface of the cell. The polycrystalline layer is generally thicker than the amorphous layer. In general, the doped layers forming the respective junctions can be independently amorphous and/or polycrystalline. To obtain better efficiencies in a series connected stack, each p-n junction can be designed to generate roughly the same photocurrent as each other. The voltages generated by each p-n junction is additive. Optional dielectric buffer layers can be placed adjacent doped layers to reduce surface recombination of electrons and holes.

In one example, a triple stack solar cell has been proposed with two microcrystalline layers and one amorphous silicon layer. This structure is described in U.S. Pat. No. 6,399,873 to Sano et al., entitled “Stacked Photovoltaic Device,” incorporated herein by reference. The amorphous silicon layer is placed on the light incident side of the cell. The microcrystalline layers can absorb longer wavelengths of light, and it is proposed that the presence of the microcrystalline layers helps to reduce light damage to the amorphous silicon. The parameters of the layers are designed for appropriate operating properties of the stack. In general, alternative numbers of stacked cells, such as two, four or more can similarly be used as an alternative to a stack of three cells connected in series. The parallel connection of solar cells in a stack is described in published U.S. patent application 2009/0242018 to Alm et al., entitled “Thin-Film Solar Cell and Fabrication Method Thereof, incorporated herein by reference.

A variety of thin film solar cell structures can advantageously incorporate polycrystalline silicon. In some embodiments, one or more semiconductor layers can be formed with a combination of amorphous silicon and polycrystalline silicon. The polycrystalline silicon portion of a composite semiconductor layer can be formed with a sintered silicon ink. The sintered silicon ink can be formed with good continuity and good electrical properties. The sintered silicon inks generally are formed into textured layers. The amorphous silicon can be deposited over the polycrystalline portion to fill the texture, or the polycrystalline layer can be placed over the amorphous layer such that the textured surface can be placed adjacent a current collector or an adjacent junction. A composite semiconducting layer can comprise from about 5 to about 60 weight percent amorphous silicon and a corresponding amount of polycrystalline silicon. As used herein, polycrystalline silicon refers to microcrystalline silicon and/or nanocrystalline silicon to refer to a silicon material having an average crystallite size from about 2 nanometers to about 10 microns.

Silicon inks are dispersions of silicon particles that are amendable to a suitable deposition process. Following deposition the silicon inks can be sintered into silicon films, which are generally polycrystalline. The resulting polycrystalline films are suitable for incorporation into thin film p-n and/or p-i-n structures. The particle within the inks can be synthesized with desired levels of dopant, which can be controlled to high dopant levels if desired.

In general, any suitable source of quality silicon inks can be used. However, laser pyrolysis has been developed as a desirable source of silicon particles for the formation of silicon inks. The silicon particles can be synthesized with a nanoscale average particle size, i.e., less than 100 nanometer average particle size. Laser pyrolysis can be used to form very uniform and pure particles, optionally with a desired dopant level. Generally, the silicon particles are synthesized as highly crystalline. The uniform nanoparticles can be formed into corresponding high quality inks. The particles can be well dispersed in the inks at relatively high concentrations, and the properties of the inks can be controlled to be suitable for the desired delivery process. For example, the inks can be formulated for use as pastes for screen printing or as suitable inks for ink jet printing. Similarly, the inks can be formulated as suitable liquids for spray coating, spin coating, knife edge coating or other coating techniques.

After depositing the inks, the silicon nano-particles can be sintered into a film. The deposited inks can first be dried. The particles can generally be sintered using any reasonable heating process to heat the particles beyond their flow temperatures. For example, the coated substrate can be heated in an oven or the like. Alternatively, laser light can be used to sinter the particles into films. In particular, ultraviolet lasers can be used to efficiently transfer energy to sinter the particles. Alternatively, longer wavelength laser light, such as green light or infrared light, can be used to penetrate deeper into a silicon coating to provide sintering of the particles into a film. The sintered film can be formed having a polycrystalline structure. The surface of the film can have some texturing reflective of the micron or nano-scale crystallites. The sintering with laser can be a relatively low temperature process with respect to the underlying substrate.

The silicon inks provide a convenient approach for the formation of one or more polycrystalline layers within a thin film solar cell structure. With polycrystalline layers formed from nanoparticle inks, the resulting films generally have surface texture corresponding with the underlying crystal structure. In some embodiments, texture can be advantageous to scatter light within the cell structure to increase absorption of the light. The ink deposition and nanoparticle sintering can be combined with other deposition approaches to achieve a synergy with the advantages provided by the respective approaches. In general, chemical vapor deposition (CVD) methods have been used to form thin film solar cell structures, although other deposition approaches can be used as desired, such as light reactive deposition, plasma deposition, physical vapor deposition or the like. Thus, one or more layers formed with a silicon ink can be used to form textured high quality polycrystalline films, and subsequently deposited layers using other deposition techniques can fill the texture to provide relatively smooth surfaces for finishing the cells. In some embodiments, the intrinsic layers can be formed from polycrystalline domains formed with sintered inks and an amorphous domain deposited with an alternative approach, such as CVD. In other embodiments, for example, a stack can comprise one p-i-n junction of amorphous silicon and another p-i-n junction formed from polycrystalline silicon resulting from a sintered ink.

The structures generally also comprise transparent conductive electrodes on the light receiving surface and a reflective and/or transparent electrode on the back side of the cell. It is generally desirable to have a reflective layer on the back side to reflect any non-absorbed light back through the cell. The front surface is generally protected with a transparent structure, such as a glass or polymer sheet. The back surface can be sealed as desired for protection of the cell. The respective electrodes can be associated with appropriate contacts to provide for electrical connection of the solar cells to an external circuit.

Thus, the use of silicon inks provides relatively low cost and convenient processing methods for the formation of high quality polycrystalline silicon films. The inks can be used to form one or more layers within desired thin film solar cells, and the resulting films can provide for desired texturing. The combination of silicon ink processing and other deposition approaches, such as conventional approaches, can provide flexibility to form appropriate thin film solar structures with desirable properties with relatively low cost and efficiently.

### Silicon Inks

As described herein, high quality dispersions of silicon nanoparticles, with or without dopants, provides the ability for effective dispersion of the silicon nanoparticles, which can be further processed to form films with desirable electronic properties. Due to the enhanced ability to control the properties of the inks, the silicon can be deposited rapidly and efficiently, for example, using reasonable printing or coating processes. The ability to introduce silicon nanoparticles with selected dopants provides the ability to form corresponding components with desired dopant levels for thin film solar cells. The inks can be formed as a stable dispersion with desirable properties suitable for selected processing approaches with relatively high loadings of silicon particles. The formation of high quality inks can be facilitated through the use of very uniform silicon nanoparticles.

The desirable dispersions described herein are based in part on the ability to form highly uniform silicon nanoparticles with or without dopants. Laser pyrolysis is a desirable technique for the production of crystalline silicon nanoparticles. In some embodiments, the particles are synthesized by laser pyrolysis in which light from an intense light source drives the reaction to form the particles from an appropriate precursor flow. Lasers are a convenient light source for laser pyrolysis, although in principle other intense, non-laser light sources can be used. The particles are synthesized in a flow that initiates at a reactant nozzle and ends at a collection system. Laser pyrolysis is useful in the formation of particles that are highly uniform in composition and size. The ability to introduce a range of precursor compositions facilitates the formation of silicon particles with selected dopants, which can be introduced at high concentrations. Additionally, laser pyrolysis can be used to manipulate the surface properties of silicon particles, although the surface properties can be further manipulated after synthesis to form desired dispersions. A description of the synthesis of silicon nanoparticles with selected compositions and a narrow distributions of average particle diameters using laser pyrolysis is described further in U.S. provisional patent application 61/359,662 to Chiruvolu et al., entitled “Silicon/Germanium Nanoparticle Inks and Associated Methods,” incorporated herein by reference.

As used herein, the term “particles” refer to physical particles, which are unfused, so that any fused primary particles are considered as an aggregate, i.e. a physical particle. For example, for particles formed by laser pyrolysis, if quenching is applied, the particles can be effectively the same as the primary particles, i.e., the primary structural element within the material. Thus, the ranges of average primary particle sizes above can also be used with respect to the particle sizes. If there is hard fusing of some primary particles, these hard fused primary particles form correspondingly larger physical particles. The primary particles can have a roughly spherical gross appearance, or they can have rod shapes, plate shapes or other non-spherical shapes. Upon closer examination, crystalline particles may have facets corresponding to the underlying crystal lattice. Amorphous particles generally have a roughly spherical aspect.

Small and uniform silicon particles can provide processing advantages with respect to forming dispersions/inks. In some embodiments, the particles have an average diameter of no more than about one micron, and in further embodiments it is desirable to have particles with smaller particle sizes to introduce desired properties. For example, nanoparticles with a small enough average particle size are observed to melt at lower temperatures than bulk material, which can be advantageous in some contexts. Also, the small particle sizes provide for the formation of inks with desirable sintering properties, which can be particularly advantageous for forming polycrystalline films with good electrical properties. Generally, the dopants and the dopant concentration are selected based on the desired electrical properties of the subsequently fused material.

In particular, for the dispersions of interest described herein, a collection of submicron/nanoscale particles may have an average diameter for the primary particles of no more than about 200 nm, in some embodiments no more than about 100 nm, alternatively no more than about 75 nm, in further embodiments from about 2 nm to about 50 nm, in additional embodiments from about 2 nm to about 25 nm, and in other embodiments from about 2 nm to about 15 nm. A person of ordinary skill in the art will recognize that other ranges within these specific ranges of average particle size contemplated and are covered by the disclosure herein. Particle diameters and primary particle diameters are evaluated by transmission electron microscopy. If the particles are not spherical, the diameter can be evaluated as averages of length measurements along the principle axes of the particle.

Because of their small size, the particles tend to form loose agglomerates due to van der Waals and other electromagnetic forces between nearby particles. Even though the particles may form loose agglomerates, the nanometer scale of the particles is clearly observable in transmission electron micrographs of the particles. The particles generally have a surface area corresponding to particles on a nanometer scale as observed in the micrographs. Furthermore, the particles can manifest unique properties due to their small size and large surface area per weight of material. These loose agglomerates can be dispersed in a liquid to a significant degree and in some embodiments approximately completely to form dispersed primary particles.

The particles can have a high degree of uniformity in size. In particular, particles generally have a distribution in sizes such that at least about 95 percent, and in some embodiments 99 percent, of the particles have a diameter greater than about 35 percent of the average diameter and less than about 280 percent of the average diameter. In additional embodiments, the particles generally have a distribution in sizes such that at least about 95 percent, and in some embodiments 99 percent, of the particles have a diameter greater than about 40 percent of the average diameter and less than about 250 percent of the average diameter. In further embodiments, the particles have a distribution of diameters such that at least about 95 percent, and in some embodiments 99 percent, of the particles have a diameter greater than about 60 percent of the average diameter and less than about 200 percent of the average diameter. A person of ordinary skill in the art will recognize that other ranges of uniformity within these specific ranges are contemplated and are within the present disclosure.

Furthermore, in some embodiments essentially no particles have an average diameter greater than about 5 times the average diameter, in other embodiments about 4 times the average diameter, in further embodiments 3 times the average diameter, and in additional embodiments 2 times the average diameter. In other words, the particle size distribution effectively does not have a tail indicative of a small number of particles with significantly larger sizes. High particle uniformity can be exploited in a variety of applications.

In addition, the submicron particles may have a very high purity level. Furthermore, crystalline nanoparticles, such as those produced by laser pyrolysis, can have a high degree of crystallinity. Similarly, the crystalline nanoparticles produced by laser pyrolysis can be subsequently heat processed to improve and/or modify the degree of crystallinity and/or the particular crystal structure.

The size of the dispersed particles can be referred to as the secondary particle size. The primary particle size is roughly the lower limit of the secondary particle size for a particular collection of particles, so that the average secondary particle size can be approximately the average primary particle size if the primary particles are substantially unfused and if the particles are effectively completely dispersed in the liquid.

The secondary or agglomerated particle size may depend on the subsequent processing of the particles following their initial formation and the composition and structure of the particles. In particular, the particle surface chemistry, properties of the dispersant, the application of disruptive forces, such as shear or sonic forces, and the like can influence the efficiency of fully dispersing the particles. Ranges of values of average secondary particle sizes are presented below with respect to the description of dispersions. Secondary particles sizes within a liquid dispersion can be measured by established approaches, such as dynamic light scattering. Suitable particle size analyzers include, for example, a Microtrac UPA instrument from Honeywell based on dynamic light scattering, a Horiba Particle Size Analyzer from Horiba, Japan and ZetaSizer Series of instruments from Malvern based on Photon Correlation Spectroscopy. The principles of dynamic light scattering for particle size measurements in liquids are well established.

In some embodiments, it is desirable to form doped nanoparticles. For example, dopants can be introduced to vary properties of the resulting particles. Laser pyrolysis can be used to introduce dopant at desired concentrations through the introduction of suitable dopant precursors into the reactant flow in desired amounts. The formation of doped silicon particles using laser pyrolysis is described further in U.S. provisional patent application 61/359,662 to Chiruvolu et al., entitled “Silicon/Germanium Nanoparticle Inks and Associated Methods,” incorporated by reference above. However, alternative doping methods can be used. In general, any reasonable element can be introduced as a dopant to achieve desired properties. For example, dopants can be introduced to change the electrical properties of the particles. In particular, As, Sb and/or P dopants can be introduced into the silicon particles to form n-type semiconducting materials in which the dopant provide excess electrons to populate the conduction bands, and B, Al, Ga and/or In can be introduced to form p-type semiconducting materials in which the dopants supply holes. In some embodiments, one or more dopants can be introduced in concentrations in the particles from about 1.0×10⁻⁷ to about 15 atomic percent relative to the silicon atoms, in further embodiments from about 1.0×10⁻⁵ to about 12.0 atomic percent and in further embodiments from about 1×10⁻⁴ to about 10.0 atomic percent relative to the silicon atoms. A person of ordinary skill in the art will recognize that additional ranges within the explicit dopant level ranges are contemplated and are within the present disclosure.

Dispersions of particular interest comprise a dispersing liquid and silicon nanoparticles dispersed within the liquid along with optional additives. Wherein particles are obtained in a powder form, the particles need to be dispersed as a step in forming the ink. The dispersion can be stable with respect to avoidance of settling over a reasonable period of time, generally at least an hour, without further mixing. A dispersion can be used as an ink, e.g., the dispersion can be printed or coated onto a substrate. The properties of the ink can be adjusted based on the particular deposition method. For example, in some embodiments, the viscosity of the ink is adjusted for the particular use, such as inkjet printing, spin coating or screen printing, and particle concentrations and additives provide some additional parameters to adjust the viscosity and other properties. The availability to form stable dispersions with small secondary particle sizes provides the ability to form certain inks that are not otherwise available.

Furthermore, it is desirable for the silicon particles to be uniform with respect to particle size and other properties. Specifically, it is desirable for the particles to have a uniform primary particle size and for the primary particles to be substantially unfused. Then, the particles generally can be dispersed to yield a smaller more uniform secondary particle size in the dispersion. Secondary particle size refers to measurements of particle size within a dispersion. The formation of a good dispersion with a small secondary particle size can be facilitated through the matching of the surface chemistry of the particles with the properties of the dispersing liquid. The surface chemistry of particles can be influenced during synthesis of the particles as well as following collection of the particles. For example, the formation of dispersions with polar solvents is facilitated if the particles have polar groups on the particle surface. As described herein, suitable approaches have been found to disperse dry nanoparticle powders, perform surface modification of the particles in a dispersion and form inks and the like for deposition.

In general, the surface chemistry of the particles influences the process of forming a dispersion. In particular, it is easier to disperse the particles to form smaller secondary particle sizes if the dispersing liquid and the particle surfaces are compatible chemically, although other parameters such as density, particle surface charge, solvent molecular structure and the like also directly influence dispersability. In some embodiments, the liquid may be selected to be appropriate for the particular use of the dispersion, such as for a printing or coating process. The surface properties of the particles can be correspondingly be adjusted for the dispersion. For silicon synthesized using silanes, the resulting silicon generally is partially hydrogenated, i.e., the silicon includes some small amount of hydrogen in the material. It is generally unclear if this hydrogen or a portion of the hydrogen is at the surface as Si—H bonds.

In general, the surface chemistry of the particles can be influenced by the synthesis approach, as well as subsequent handling of the particles. The surface by its nature represents a termination of the underlying solid state structure of the particle. This termination of the surface of the silicon particles can involve truncation of the silicon lattice. The termination of particular particles influences the surface chemistry of the particles. The nature of the reactants, reaction conditions, and by-products during particle synthesis influences the surface chemistry of the particles collected as a powder during flow reactions. The silicon can be terminated, for example, with bonds to hydrogen, as noted above. In some embodiments, the silicon particles can become surface oxidized, for example through exposure to air. For these embodiments, the surface can have bridging oxygen atoms in Si—O—Si structures or Si—O—H groups if hydrogen is available during the oxidation process.

In some embodiments, the surface properties of the particles can be modified through surface modification of the particles with a surface modifying composition. Surface modification of the particles can influence the dispersion properties of the particles as well as the solvents that are suitable for dispersing the particles. Some surface active agents, such as many surfactants, act through non-bonding interactions with the particle surfaces. In some embodiments, desirable properties are obtained through the use of surface modification agents that chemically bond to the particle surface. The surface chemistry of the particles influences the selection of surface modification agents. The use of surface modifying agents to alter the silicon particle surface properties is described further in published U.S. patent application 2008/0160265 to Hieslmair et al., entitled “Silicon/Germanium Particle Inks, Doped Particles, Printing, and Processes for Semiconductor Applications,” incorporated herein by reference. While surface modified particles can be designed for use with particular solvents, it has been found that desirable inks can be formed without surface modification at high particle concentrations and with good deliverability. The ability to form desired inks without surface modification can be useful for the formation of desired devices with a lower level of contamination.

When processing a dry, as-synthesized powder, it has been found that forming a good dispersion of the particles prior to further processing facilitates the subsequent processing steps. The dispersion of the as-synthesized particles generally comprises the selection of a solvent that is relatively compatible with the particles based on the surface chemistry of the particles. Shear, stirring, sonication or other appropriate mixing conditions can be applied to facilitate the formation of the dispersion. In general, it is desirable for the particles to be well dispersed, although the particles do not need to be stably dispersed initially if the particles are subsequently transferred to another liquid. For particular applications, there may be fairly specific target properties of the inks as well as the corresponding liquids used in formulating the inks. Furthermore, it can be desirable to increase the particle concentration of a dispersion/ink relative to an initial concentration used to form a good dispersion.

One approach for changing solvents involves the addition of a liquid that destabilizes the dispersion. The liquid blend then can be substantially separated from the particles through decanting or the like. The particles then can be re-dispersed in the newly selected liquid. This approach for changing solvents is discussed in published U.S. patent application 2008/016065 to Hieslmair et al., entitled “Silicon/Germanium Particle Inks, Doped Particles, Printing and Processes for Semiconductor Applications,” incorporated herein by reference.

With respect to the increase of particle concentration, solvent can be removed through evaporation to increase the concentration. This solvent removal generally can be done appropriately without destabilizing the dispersion. Similarly, solvent blends can be formed. A lower boiling solvent component can be removed preferentially through evaporation. If the solvent blend forms an azeotrope, a combination of evaporation and further solvent addition can be used to obtain a target solvent blend. Solvent blends can be particularly useful for the formation of ink compositions since the blends can have liquid that contribute desirable properties to the ink. A low boiling temperature solvent component can evaporate relatively quickly after deposition to stabilize the deposited ink prior to further processing and curing. A higher temperature solvent component can be used to adjust the viscosity to limit spreading after deposition.

At appropriate stages of the dispersion process, the dispersion can be filtered to remove contaminants and/or any stray unusually large particles. Generally, the filter is selected to exclude particulates that are much larger than the average secondary particle size so that the filtration process can be performed in a reasonable way. In general, the filtration processes have not been suitable for overall improvement of the dispersion quality. Suitable commercial filters are available, and can be selected based on the dispersion qualities and volumes.

The dispersions can be formulated for a selected application. The dispersions can be characterized with respect to composition as well as the characterization of the particles within the dispersions. In general, the term ink is used to describe a dispersion, and an ink may or may not include additional additives to modify the ink properties.

Better dispersions are more stable and/or have a smaller secondary particle size indicating less agglomeration. As used herein, stable dispersions have no settling without continuing mixing after one hour. In some embodiments, the dispersions exhibit no settling of particles without additional mixing after one day and in further embodiments after one week, and in additional embodiments after one month. In general, dispersions with well dispersed particles can be formed at concentrations of at least up to 30 weight percent inorganic particles. Generally, for some embodiments it is desirable to have dispersions with a particle concentration of at least about 0.05 weight percent, in other embodiments at least about 0.25 weight percent, in additional embodiments from about 0.5 weight percent to about 25 weight percent and in further embodiments from about 1 weight percent to about 20 weight percent. A person of ordinary skill in the art will recognize that additional ranges of stability times and concentrations within the explicit ranges above are contemplated and are within the present disclosure.

The dispersions can include additional compositions besides the silicon particles and the dispersing liquid or liquid blend to modify the properties of the dispersion to facilitate the particular application. For example, property modifiers can be added to the dispersion to facilitate the deposition process. Surfactants can be effectively added to the dispersion to influence the properties of the dispersion.

In general, cationic, anionic, zwitter-ionic and nonionic surfactants can be helpful in particular applications. In some applications, the surfactant further stabilizes the particle dispersions. For these applications, the selection of the surfactant can be influenced by the particular dispersing liquid as well as the properties of the particle surfaces. In general, surfactants are known in the art. Furthermore, the surfactants can be selected to influence the wetting or beading of the dispersion/ink onto the substrate surface following deposition of the dispersion. In some applications, it may be desirable for the dispersion to wet the surface, while in other applications it may be desirable for the dispersion to bead on the surface. The surface tension on the particular surface is influenced by the surfactant. Also, blends of surfactants can be helpful to combine the desired features of different surfactants, such as improve the dispersion stability and obtaining desired wetting properties following deposition. In some embodiments, the dispersions can have surfactant concentrations from about 0.01 to about 5 weight percent, and in further embodiments from about 0.02 to about 3 weight percent.

The use of non-ionic surfactants in printer inks is described further in U.S. Pat. No. 6,821,329 to Choy, entitled “Ink Compositions and Methods of Ink-Jet Printing on Hydrophobic Media,” incorporated herein by reference. Suitable non-ionic surfactants described in this reference include, for example, organo-silicone surfactants, such as SILWET™ surfactants from Crompton Corp., polyethylene oxides, alkyl polyethylene oxides, other polyethylene oxide derivatives, some of which are sold under the trade names, TERGITOL™, BRIJ™, TRITON™, PLURONIC™, PLURAFAC™, IGEPALE™, and SULFYNOL™ from commercial manufacturers Union Carbide Corp., ICI Group, Rhone-Poulenc Co., Rhom & Haas Co., BASF Group and Air Products Inc. Other nonionic surfactants include MACKAM™ octylamine chloroacetic adducts from McIntyre Group and FLUORAD™ fluorosurfactants from 3M. The use of cationic surfactants and anionic surfactants for printing inks is described in U.S. Pat. No. 6,793,724 to Satoh et al., entitled “Ink for Ink-Jet Recording and Color Ink Set,” incorporated herein by reference. This patent describes examples of anionic surfactants such as polyoxyethylene alkyl ether sulfate salt and polyoxyalkyl ether phosphate salt, and examples of cationic surfactants, such as quaternary ammonium salts.

Viscosity modifiers can be added to alter the viscosity of the dispersions. Suitable viscosity modifiers include, for example soluble polymers, such as polyacrylic acid, polyvinyl pyrrolidone and polyvinyl alcohol. Other potential additives include, for example, pH adjusting agents, antioxidants, UV absorbers, antiseptic agents and the like. These additional additives are generally present in amounts of no more than about 5 weight percent. A person of ordinary skill in the art will recognize that additional ranges of surfactant and additive concentrations within the explicit ranges herein are contemplated and are within the present disclosure.

For electronic applications, it can be desirable to remove organic components to the ink prior to or during certain processing steps such that the product materials are effectively free from carbon. In general, organic liquids can be evaporated to remove them from the deposited material. However, surfactants, surface modifying agents and other property modifiers may not be removable through evaporation, although they can be removed through heating at moderate temperature in an oxygen atmosphere to combust the organic materials.

The use and removal of surfactants for forming metal oxide powders is U.S. Pat. No. 6,752,979 to Talbot et al., entitled “Production of Metal Oxide Particles with Nano-Sized Grains,” incorporated herein by reference. The '979 patent teaches suitable non-ionic surfactants, cationic surfactants, anionic surfactants and zwitter-ionic surfactants. The removal of the surfactants involves heating of the surfactants to moderate temperatures, such as to 200° C. in an oxygen atmosphere to combust the surfactant. Other organic additives generally can be combusted for removal analogously with the surfactants. If the substrate surface is sensitive to oxidation during the combustion process, a reducing step can be used following the combustion to return the surface to its original state.

The Z-average particle sizes can be measured using dynamic light scattering. The Z-average particle size is based on a scattering intensity weighted distribution as a function of particle size. Evaluation of this distribution is prescribed in ISO International Standard 13321, Methods for Determination of Particle Size Distribution Part 8: Photon Correlation Spectroscopy, 1996, incorporated herein by reference. The Z-average distributions are based on a single exponential fit to time correlation functions. However, small particles scatter light with less intensity relative to their volume contribution to the dispersion. The intensity weighted distribution can be converted to a volume-weighted distribution that is perhaps more conceptually relevant for evaluating the properties of a dispersion. For nanoscale particles, the volume-based distribution can be evaluated from the intensity distribution using Mie Theory. The volume-average particle size can be evaluated from the volume-based particle size distribution. Further description of the manipulation of the secondary particle size distributions can be found in Malvern Instruments—DLS Technical Note MRK656-01, incorporated herein by reference.

In general, if processed appropriately, for dispersions with well dispersed particles, the Z-average secondary particle size can be no more than a factor of four times the average primary particle size, in further embodiments no more than about 3 times the average primary particle size and in additional embodiments no more than about 2 times the average primary particle size. In some embodiments, the Z-average particle size is no more than about 1 micron, in further embodiments no more than about 250 nm, in additional embodiments no more than about 100 nm, in other embodiments no more than about 75 nm and in some embodiments from about 5 nm to about 50 nm. With respect to the particle size distribution, in some embodiment, essentially all of the secondary particles can have a size no more than 5 times the Z-average secondary particle size, in further embodiments no more than about 4 times the Z-average particle size and in other embodiments no more than about 3 times the Z-average particle size. Furthermore, the DLS particle size distribution can have in some embodiments a full width at half-height of no more than about 50 percent of the Z-average particle size. Also, the secondary particles can have a distribution in sizes such that at least about 95 percent of the particles have a diameter greater than about 40 percent of the Z-average particle size and less than about 250 percent of the Z-average particle size. In further embodiments, the secondary particles can have a distribution of particle sizes such that at least about 95 percent of the particles have a particle size greater than about 60 percent of the Z-average particle size and less than about 200 percent of the Z-average particle size. A person of ordinary skill in the art will recognize that additional ranges of particle sizes and distributions within the explicit ranges above are contemplated and are within the present disclosure.

The viscosity of the dispersion/ink is dependent on the silicon particle concentration as well as the other additives. Thus, there are several parameters that provide for adjustment of the viscosity. Generally, printing and coating processes may have desired viscosity ranges and/or surface tension ranges. For some embodiments, the viscosity can be from 0.1 mPa·s to about 100 mPa·s and in further embodiments from about 0.5 mPa·s to about 25 mPa·s. For some embodiments, the dispersions/inks can have a surface tension from about 2.0 to about 6.0 N/m² and in further embodiments from about 2.2 to about 5.0 N/m² and in additional embodiments form about 2.5 to about 4.5 N/m². In some embodiments, the silicon inks form a non-Newtonian fluid, and this can be appropriate for corresponding coating/printing approaches. For example, for screen printing, the inks or pastes are generally non-Newtonian. For a non-Newtonian fluid, the viscosity depends on the shear rate. For these materials, the viscosity of the ink can be selected based on the shear range used for the corresponding deposition approach. Thus, for screen printing the shear rate can be, for example, in the range form about 100 s⁻¹ to about 10,000 s⁻¹, and the viscosity at the desired shear rate can be from about 500 mPa·s to about 500,000 mPa·s, in additional embodiments from about 750 mPa·s to about 250,000 mPa·s, and in further embodiments from about 1000 mPa·s to about 100,000 mPa·s. A person of ordinary skill in the art will recognize that additional ranges of viscosity and surface tension within the explicit ranges above are contemplated and are within the present disclosure.

The dispersions/inks can be formed using the application of appropriate mixing conditions. For example, mixers/blenders that apply shear can be used and/or sonication can be used to mix the dispersions. The particular additives can be added in an appropriate order to maintain the stability of the particle dispersion. A person of ordinary skill in the art can select the additives and mixing conditions empirically based on the teachings herein.

The dispersions/inks can be deposited for using a selected approach that achieves a desired distribution of the dispersion on a substrate. For example, coating and printing techniques can be used to apply the ink to a surface. Following deposition, the deposited material can be further processed into a desired device or state.

Suitable coating approaches for the application of the dispersions include, for example, spin coatings, dip coating, spray coating, knife-edge coating, extrusion or the like. Similarly, a range of printing techniques can be used to print the dispersion/ink into a pattern on a substrate. Suitable printing techniques include, for example, screen printing, inkjet printing, lithographic printing, gravure printing and the like. In general, any reasonable coating thickness can be applied. For thin film solar cell components, average coating thickness can range from about 1 nm to about 20 microns and in further embodiments from about 2 nm to about 15 microns. A person of ordinary skill in the art will recognize that additional ranges of average thicknesses within the particular ranges above are contemplated and are within the present disclosure.

For the formation of thin film solar cell components, various coating techniques and screen printing can offer desirable features for depositing the silicon inks. In some embodiments, the pastes for screen printing may have a greater silicon particle concentration relative to concentrations suitable for other deposition approaches. In some embodiments, spin coating can be a convenient coating approach for forming a layer of silicon ink.

For screen printing, the formulations are prepared as a paste that can be delivered through the screen. The screens generally are reused repeatedly. The solvent systems for the paste should be selected to both provide desired printing properties and to be compatible with the screens so that the screens are not damaged by the paste. The use of a solvent blend provides for the rapid evaporation of a low boiling temperature solvent while using a higher boiling solvent to control the viscosity. The high boiling solvent generally can be removed more slowly without excessive blurring of the printed image. After removal of the higher boiling temperature solvent, the printed silicon particles can be cured, or further processed into the desired device.

Suitable lower boiling point solvents include, for example, isopropyl alcohol, propylene glycol or combinations thereof. Suitable higher boiling point solvents include, for examples, N-methylpyrrolidone, dimethylformamide, terpineols, such as α-terpineol, carbitol, butyl cellosolve, or combinations thereof. The screen printing paste can further include a surfactant and/or a viscosity modifier. In general, the screen printable ink or paste are very viscous and can be desired to have a viscosity from about 10 Pa·s to about 300 Pa·s, and in further embodiments from about 50 Pa·s to about 250 Pa·s. The screen printable inks can have a silicon particle concentration from about 5 weight percent to about 25 weight percent silicon particles. Also, the screen printable inks can have from 0 to about 10 weight percent lower boiling solvent, in further embodiments from about 0.5 to about 8 and in other embodiments from about 1 to about 7 weight percent lower boiling solvent. A person of ordinary skill in the art will recognize that additional composition and property ranges within the explicit ranges above are contemplated and are within the present disclosure. The description of screen printable pastes for the formation of electrical components is described further in U.S. Pat. No. 5,801,108 to Huang et al., entitled “Low Temperature Curable Dielectric Paste,” incorporated herein by reference, although the dielectric paste comprises additives that are not suitable for the semiconductor pastes/inks described herein.

In general, following deposition, the liquid evaporates to leave the particles and any other non-volatile components of the inks remaining. For some embodiments with suitable substrates that tolerates suitable temperatures and with organic ink additives, if the additives have been properly selected, the additives can be removed through the addition of heat in an appropriate oxygen atmosphere to remove the additives, as described above. The sintering of the inks into films is described below.

### Thin Film Solar Cell Structures

The thin film solar cell structures generally comprise elemental silicon forming a p-n diode junction, and in some embodiments of interest an intrinsic silicon layer, with no dopant or a very low dopant level, is placed between the p-doped layer and the n-doped layer. With respect to the solar cell structures formed with the silicon inks, the structures can generally comprise one or more polycrystalline layers. The silicon inks can be sintered to form good electrical connectivity within the layer. The alternating layers of doped and/or undoped semiconductor materials can be placed between substantially transparent electrodes and/or a transparent electrode at the light receiving surface and a reflective electrode at the back surface. The polycrystalline layers formed from the inks can have a texture. The polycrystalline silicon film formed from an ink can be combined within a layer with an amorphous silicon material. If the texture of a polycrystalline layer is used to form a textured interface with a buffer layer and/or an electrode layer, scattering can result that enhances internal reflections of light within the solar cell absorbing films that results in increased absorption of the light.

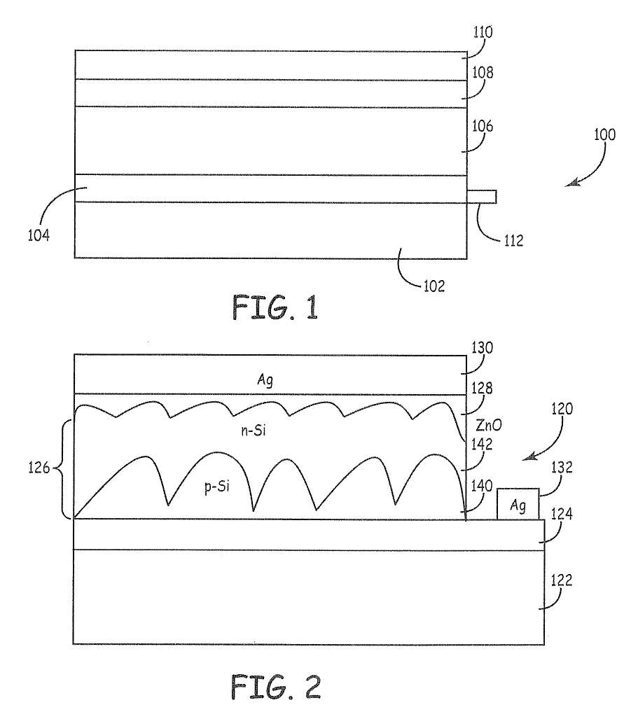

Referring to FIG. 1, the cross section of an embodiment of a thin film silicon-based solar cell is shown schematically. Solar cell 100 comprises a front transparent layer 102, a front transparent electrode 104, photovoltaic element 106, a back electrode 108, a reflective layer 110, which can also function as a current collector, and current collector 112 associated with front transparent electrode 104. The structure can further comprise a thin buffer layer adjacent to a doped-layer to reduce surface recombination, and some specific embodiments of buffer layers are described further below. In some embodiments, back electrode 108 can also function as a reflective layer and current collector as an alternative to a transparent electrode.

Front transparent layer 102 provides for light access to photovoltaic element 106 through front transparent electrode 104. Front transparent layer 102 can provide some structural support for the overall structure as well as providing protection of the semiconductor material from environmental assaults. Thus, in use, the front layer 102 is placed to receive light, generally sun light, to operate the solar cell. In general, front transparent layer can be formed from inorganic glasses, such as silica-based glasses, polymers, such as polycarbonates, polysiloxanes, polyamides, polyimides, polyethylenes, polyesters, combinations thereof, composites thereof or the like. The transparent front sheet can have an antireflective coating and/or other optical coating on one or both surfaces.

Front transparent electrode 104 generally comprises a substantially transparent electrically conductive material, such as a conductive metal oxide. Front transparent electrode 104 permits light received through front transparent layer 102 to be transmitted to photovoltaic element 106 and can have electrical contact with photovoltaic element 106 and current collector 112. If back electrode 108 comprises a substantially transparent conductive material, light received by back electrode 108 is transmitted to reflective layer 110 and permits light to be reflected back to photovoltaic element 106. Back electrode 108 also has electrical contact with photovoltaic element 106. Front transparent electrode 104 and/or back electrode 108 can be formed to have a surface structure that increases light scattering within photovoltaic element 106. Increasing light scattering within photovoltaic element 106 can produce improved photoelectric conversion efficiency of solar cell 100.

Current collectors 110 and 112 can be formed, for example, from elemental metal. Layers of metal, such as silver, aluminum and nickel can provide very good electrical conductivity and a high reflectivity, although other metals can also be used. Current collector 110 can be formed at any reasonable thickness. Front transparent electrode 104 and back electrode 108 can be formed from transparent conductive metal oxides (TCO). Suitable conductive oxides include, for example, zinc oxide doped with aluminum oxide, indium oxide doped with tin oxide (indium tin oxide, ITO) or fluorine doped tin oxide.

Photovoltaic element 106 comprises silicon based semiconductors forming a p-n diode junction, which may further comprise an intrinsic silicon layer to form a p-i-n. As noted above, the thin film solar cell can comprise a stack with a plurality of p-n junctions. In generally, one or more layers within photovoltaic element 106 can comprise polycrystalline silicon formed from a silicon ink. The polycrystalline layer or layers formed from silicon ink can be intrinsic, p-doped and/or n-doped. In some embodiments, the p-n junction forms the photovoltaic element with the p-doped silicon layer in contact with the n-doped silicon layer. In some embodiments, if the doped layers are adjacent a polycrystalline intrinsic layer, one or both of the doped layers can be formed with polycrystalline silicon and optionally one or both layers can be formed with amorphous silicon.

An example embodiment of a thin film solar cell with a p-n junction formed with polycrystalline silicon films formed with silicon inks is shown in FIG. 2. Thin film solar cell 120 comprises a glass layer 122, a front electrode 124, photovoltaic element 126, a back transparent electrode 128, a reflective current collector layer 130, and current collector 132 associated with front electrode 124. Back transparent electrode layer 128 can be eliminated so that reflective current collector layer 130 can be directly in contact with photovoltaic element 126. As shown in FIG. 2, photovoltaic element 126 comprises polycrystalline p-doped silicon layer 140 and polycrystalline n-doped silicon layer 142. Polycrystalline doped silicon layers 140, 142 can be formed with silicon inks, and the layers formed form inks can have texture. Characteristics of the silicon films formed form silicon inks are described further below. In alternative embodiments, one of the doped silicon films can be replaced with polycrystalline films formed from a non-silicon ink process or with a doped amorphous silicon film.

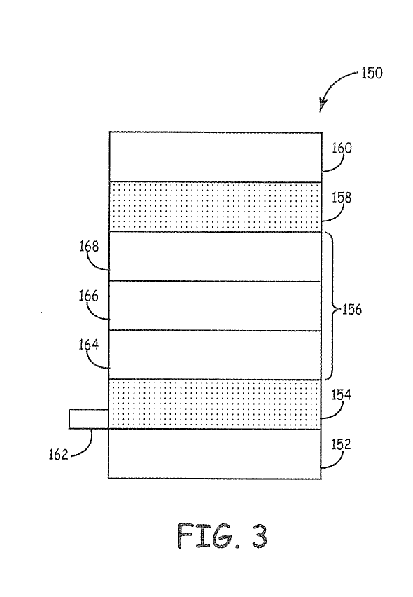

In some embodiments, the photovoltaic element has an intrinsic silicon layer between the n-doped layer and the p-doped layer to form a p-i-n structure. The intrinsic silicon layer can be made thicker than the doped layers to absorb more of the light reaching the photovoltaic element. An embodiment of a thin film solar cell with a p-i-n structure is shown in FIG. 3. Thin film solar cell 150 comprises a transparent protective layer 152, a front transparent electrode 154, photovoltaic element 156, a back transparent electrode 158, a reflective current collector layer 160, and current collector 162 associated with front electrode 154. Referring to FIG. 3, photovoltaic element 156 comprises p-i-n structure comprising a p-doped semiconductor layer 164, an intrinsic semiconductor layer 166, and an n-doped semiconductor layer 168.

In both the p-n junction and the p-i-n junction, an electric field generally develops across junction due to the migration of electrons and holes across the junction. If light is absorbed by the photovoltaic element, the conductive electrons and holes move in response to the electric field to create a photocurrent. If semiconductor layer 112 and semiconductor layer 116 are connected via an external conducting pathway, the photocurrent can be harvested at a voltage determined by the nature of the junction. Generally, the p-doped semiconductor layer is placed toward the light receiving side to receive the greater light intensity since electrons moving from the p-doped semiconductor have greater mobility than the corresponding holes.

In embodiments of particular interest, at least one semiconductor layer in the p-i-n junction of 164, 166, 168 is a polycrystalline film formed from a silicon ink. In some embodiments, each of layers 164, 166, 168 is polycrystalline, and one or all of the layers can be formed with a silicon ink with corresponding properties. In some embodiments, semiconductor layers 164, 166 are polycrystalline layers formed with a silicon ink and n-doped semiconductor layer 168 is formed from a deposition technique such as CVD. In alternative embodiments, all or a portion of one semiconductor layer can be amorphous. For example, it can be desirable for the intrinsic layer to comprise an amorphous portion and a polycrystalline portion.

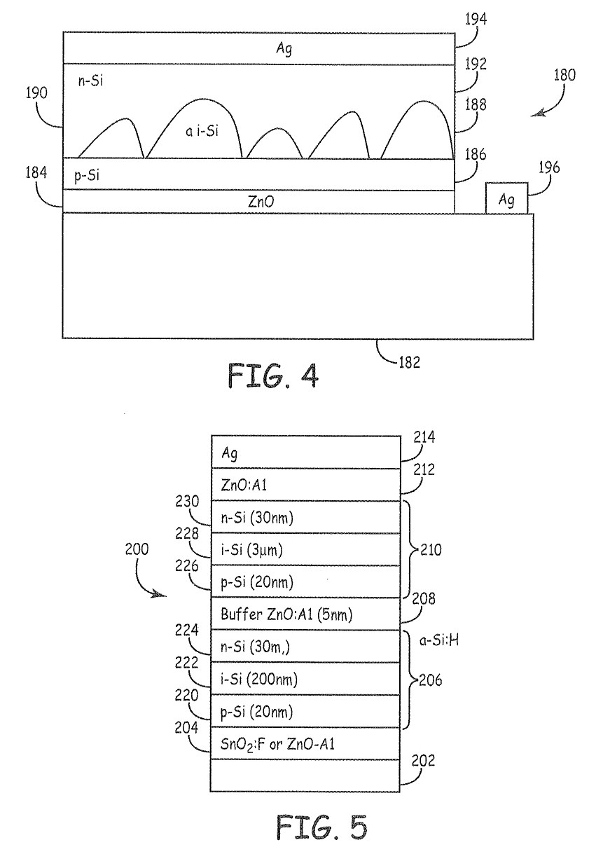

One embodiment of a solar cell structure with an intrinsic semiconductor layer having a polycrystalline portion and an amorphous portion as a composite layer is shown schematically in FIG. 4. Thin film solar cell 180 comprises a transparent protective layer 182, a front transparent electrode 184, a polycrystalline p-doped silicon layer 186, a polycrystalline intrinsic silicon layer 188, an amorphous intrinsic silicon layer 190, an amorphous n-doped silicon layer 192, a reflective current collector layer 194, and current collector 196 associated with front electrode 184. Note that a back transparent electrode is not used in this embodiment, although a back transparent electrode can be incorporated if desired. Polycrystalline p-doped silicon layer 186 and/or polycrystalline intrinsic silicon layer 188 can be formed from a sintered silicon ink to provide corresponding structural properties. Amorphous silicon layers 190, 192 can be deposited using appropriate techniques, such as CVD, as described further below and the amorphous layers may fill texture from the polycrystalline layers possibly to at least partially smooth the surface of the amorphous layers relative to the texture of the polycrystalline layers. In alternative or additional embodiments, the p-doped silicon layer can be amorphous and/or the n-doped silicon layer can be polycrystalline. Thus, the doped layers can both be amorphous with the composite intrinsic layer between. Also, the relative orientation of the amorphous film and the polycrystalline film can be reversed so that the amorphous silicon is on average closer the light receiving surface relative to the polycrystalline intrinsic silicon film. The photovoltaic element shown in FIG. 4 can be incorporated into a stacked thin film solar cell structure also.

If the polycrystalline material is incorporated into the same layer as amorphous silicon, the relative amounts of the materials cm be selected based on the absorption and stability properties without regard for current generation from the respective materials. Thus, the composite layer can comprise from about 5 weight percent to about 90 weight percent amorphous silicon, in further embodiments from about 7.5 to about 60 weight percent, and in other embodiments from about 10 to about 50 weight percent amorphous silicon. Correspondingly, the composite layer can comprise from about 10 to about 95 weight percent polycrystalline silicon, in further embodiments from about 40 to about 92.5 weight percent polycrystalline silicon and in other embodiments from about 50 to about 90 weight percent polycrystalline silicon. The interface between the polycrystalline silicon and the amorphous silicon may be textured with features of the texture corresponding to the crystallite size in the polycrystalline silicon material. A person of ordinary skill in the art will recognize that additional ranges of composition within the explicit composite composition ranges above are contemplated and are within the present disclosure.

As noted above, a thin film solar cell can comprise a plurality of p-i-n junctions. Referring to FIG. 5, a stacked silicon-based solar cell 200 comprises a plurality of photovoltaic elements. Specifically, solar cell 200 comprises a front transparent layer 202, a front electrode 204, a first photovoltaic element 206, a buffer layer 208, a second photovoltaic element 210, a back transparent electrode 212, and a reflecting layer/current collector 214. Solar cell 200 can be formed without buffer layer 208. Also, solar cell 200 can be formed without back transparent electrode 212, in which case current collector 214 functions as a reflective back electrode.

In general, a variety of structures can be used for photovoltaic elements 206, 210. The use of a plurality of photovoltaic elements can be used to provide for absorption of a greater amount of the incident light. Elements 206 and 210 may or may not have equivalent structures, and any of the photovoltaic element structures described above can be used for each element. However, in some embodiments, photovoltaic element 206 comprises amorphous silicon, and photovoltaic element 210 comprises at least one layer of polycrystalline silicon. For example, photovoltaic element 210 can comprise a specific structure of a photovoltaic element such as shown in FIG. 5.

Referring to FIG. 5, photovoltaic element 210 comprises three layers of polycrystalline silicon. In particular, in the specific embodiment of FIG. 5, photovoltaics element 206 comprises amorphous p-doped silicon layer 220, amorphous intrinsic silicon layer 222, amorphous n-doped silicon layer 224. Photovoltaic element 210 comprises polycrystalline p-doped silicon layer 226, polycrystalline intrinsic silicon layer 228 and polycrystalline n-doped silicon layer 230. One or more of the polycrystalline silicon layers 226, 228, 230 can be formed from silicon inks, and generally it is desirable to form at least the polycrystalline intrinsic silicon layer with a silicon ink.

With respect to a stacked configuration of photovoltaic elements, photovoltaic elements 206 and 210 can be formed to desirably increase photoelectric conversion efficiency of solar cell 200. In particular, photovoltaic element 206 can be designed to absorb light at a first range of wavelengths and photovoltaic element 210 can be designed to absorb light at a second range of wavelengths that is not the same as first range of wavelengths, although the ranges are generally significantly overlapping. For example, this improvement in photoelectric conversion efficiency can be accomplished with the specific structure in FIG. 5 since photovoltaic element 210 with polycrystalline silicon can generally absorb a greater amount of light at longer wavelengths relative to photovoltaic element 206 with amorphous silicon.

It can be desirable to form photovoltaic elements of a stacked solar cell such that the current through each photovoltaic element is substantially the same within desired bounds. The voltage of a stacked solar cell formed from a plurality of photovoltaic elements connected in series is substantially the sum of the voltages across each photovoltaic element. The current through a stacked solar cell formed from a plurality of photovoltaic elements connected in series is generally a value that is substantially the current of the photovoltaic element generating the smallest current. The thickness of the thin films which forms each photovoltaic element can be adjusted based on the target of matching the current through each respective photovoltaic element.

In general, for any of the embodiments above, the intrinsic silicon material has a low impurity and/or dopant level. For the polycrystalline intrinsic silicon, it may be desirable to include a low level of n-type dopant to increase mobilities, such as no more than about 25 ppm by weight, in some embodiments no more than about 12 ppm by weight, in further embodiments no more than about 8 ppm by weight and in additional embodiment from 0.002 ppm to about 1 ppm (about 1×10¹⁴ atoms/cm³ to about 5×10¹⁶ atoms/cm³). The n-doped and p-doped silicon materials generally can have a high dopant concentration such as from about 0.01 atomic percent to about 50 atomic percent, in additional embodiments from about 0.05 atomic percent to about 35 atomic percent and in further embodiments from about 0.1 atomic percent to about 15 atomic percent. Expressed in other units, the doped materials can comprise at least about 5×10¹⁸ atoms/cm³ and in other embodiments from about 1×10¹⁹ atoms/cm³ to about 5×10²¹ atoms/cm³. Various units for dopant concentration for the doped materials can be related as follows: 1 atomic percent=11,126 ppm by weight=5×10²⁰ atoms/cm³. A person of ordinary skill in the art will recognize that additional composition ranges within the explicit dopant composition ranges above are contemplated and are within the present disclosure.

In general, the silicon materials also comprise H atoms and/or halogen atoms. The hydrogen atoms can occupy otherwise dangling bonds which can improve carrier mobilities and lifetimes. In general, the silicon materials can comprise from about 0.1 to about 50 atomic percent hydrogen and/or halogen atoms, in further embodiments from about 0.25 to about 45 atomic percent and in additional embodiments from about 0.5 to about 40 atomic percent hydrogen and/or halogen atoms. A person of ordinary skill in the art will recognize that additional hydrogen/halogen concentration ranges within the explicit ranges above are contemplated and are within the present disclosure. As used herein, hydrogen and halogens are not considered dopants.

With respect to the average thicknesses of the doped layers, the doped layers generally can have thicknesses from about 1 nm, to about 100 nm, in further embodiments from about 2 nm to about 60 nm and in other embodiments from about 3 nm to about 45 nm. The amorphous intrinsic layers can have average thicknesses from about 40 nm to about 400 nm and in further embodiments from about 60 nm to about 250 nm. The polycrystalline intrinsic layers can have average thicknesses from about 200 nm to about 10 microns, in other embodiments from about 300 nm to about 5 microns and in further embodiments from about 400 nm to about 4 microns. For layers formed from sintered silicon inks, the film can have a surface coverage of at least about 75%, in further embodiments at least about 80% and in additional embodiments at least about 85%, and surface coverage can be evaluated by visual review of a scanning electron micrograph. A person of ordinary skill in the art will recognize that additional ranges within the explicit ranges are contemplated and are within the present disclosure.

In embodiments having a composite layer with both amorphous silicon and polycrystalline silicon with similar dopant levels or lack thereof, the composite layer can be structured with the polycrystalline domain formed from a silicon ink having a textured surface and the amorphous domain adjacent the polycrystalline domain, possibly smoothing the texture, with the domains on average forming layers with corresponding layer thicknesses. The texturing generally reflects the crystallite size accounting for packing that may cover the layer. The composite layer can comprise from about 0.1 to about 70 weight percent amorphous silicon, in further embodiments from about 0.5 to about 35 weight percent amorphous silicon, in some embodiments from about 1 to about 20 weight percent amorphous silicon and in additional embodiments from about 2 to about 15 weight percent amorphous silicon with the remainder of the remainder of the layer being essentially polycrystalline silicon. The amorphous silicon and the polycrystalline silicon in the composite layer can have approximately equivalent dopant or alternatively they can have suitable dopants levels suitable for the average properties of the layer, e.g., intrinsic or doped, although somewhat different levels than each other. A person of ordinary skill in the art will recognize that additional ranges of compositions within the explicit ranges above are contemplated and are within the present disclosure.

In general, the structure can comprise additional layers, such as buffer layers or the like. Buffer layers can be thin layers of non-silicon material, such as silicon carbide, zinc oxide optionally doped with aluminum or other suitable material. In some embodiments, the buffer layer can have an average thickness, for example, from about to 1 nm to about 100 nm and in further embodiments, the buffer layer can have an average thickness form about 2 nm to about 50 nm. A person of ordinary skill in the art will recognize that additional ranges of average buffer layer thickness within the explicit ranges above are contemplated and are within the present disclosure.

### Processing to Form Solar Cells

Based on the processing approaches described herein, silicon inks provide a convenient precursor for the formation of one or more components of a thin film solar cell. In particular, the silicon ink can be used conveniently for the formation of polycrystalline layers. For the formation of the entire thin film solar cell structure, the overall process can combine steps based on one or more silicon inks with other processing approaches, such as conventional processing approaches, e.g., chemical vapor deposition steps.

In general, a thin film solar cell is built up from a substrate. For example, the transparent front layer can be used as a substrate for forming the cell. Generally, the solar cell is built a layer at a time, and the completed cell has current collectors that provide for connection of the cell to an external circuit generally comprising an appropriate number of cell connected in series and/or in parallel.

In general, one or more layers within the thin film structure can be formed efficiently using silicon inks that are deposited and sintered, and one or more layers generally are deposited using an alternative deposition technique. Suitable additional techniques include chemical vapor deposition (CVD) and variations thereof, light reactive deposition, physical vapor deposition, such as sputtering, and the like. Light reactive deposition (LRD) can be a relatively rapid deposition technique, and while LRD is generally effective for forming porous coatings which can be sintered to form dense layers, LRD has been adapted for dense coating deposition. LRD is described generally in U.S. Pat. Nos. 7,575,784 to Bi et al., entitled “Coating Formation by Reactive Deposition,” and 7,491,431 to Chiruvolu et al., entitled “Dense Coating Formation by Reactive Deposition,” both of which are incorporated herein by reference. LRD has been adapted for the deposition of silicon and doped silicon, as described in published U.S. patent application 2007/0212510 to Hieslmair et al., “Thin Silicon or Germanium Sheets and Photovoltaics Formed From Thin Sheets,” incorporated herein by reference.

While other deposition techniques can be effectively employed, plasma enhanced-CVD or PECVD has been developed as a tool for depositing layers for thin film solar cells such that control can be obtained to selectively deposit amorphous silicon, polycrystalline silicon and doped versions thereof as well as transparent conductive electrodes. Thus, it may be desirable to combine PECVD with deposition of one or more layers with a silicon ink to form the solar cell. In a PECVD process, precursor gasses or a portion thereof are first partially ionized before being reacted and/or deposited on a substrate. Ionization of the precursor gasses can increase reaction rates and can allow for lower film formation temperatures.

In some embodiments, a PECVD apparatus generally comprises a film forming chamber in which the thin film is formed under reduced pressure conditions. To facilitate processing, the apparatus can further comprise a supply chamber, an exit chamber, and a conveyor for transporting a substrate. In operation, a substrate is placed in the film forming chamber, and the PECVD apparatus is evacuated with pump to a predetermined pressure. Processing steps with the silicon ink may or may not be performed in the same chamber in which the CVD process is performed, although the ink processing generally is not performed at the low pressures used for CVD due to the presence of solvents. The conveyor can be used to transport the substrate between chambers for the performance of different processing steps if desired.

For performing PECVD, the film forming chamber can comprise a reactant source, an electrode pair, a high frequency (e.g., RF, VHF or microwave) power source, a temperature controller, and an exhaust port. The reactant source introduces a precursor gas between the electrode pair. A precursor gas can comprise a plurality of gasses. High frequency power can be provided from the power source to the electrodes. The electrodes can at least partially ionizing some or all of the precursor gas within the film forming chamber. Without being limited to a theory, it is believed that an enhanced supply of reactive precursor free radicals generated by ionization makes possible the deposition of dense films at lower temperatures and faster deposition rates relative to non-plasma enhanced CVD techniques. Within the film forming chamber, the temperature of the substrate and the pressure of the chamber can be controlled with the temperature controller and the exhaust port, respectively. Desirable temperatures for formation of thin films of interest herein using PECVD can be from about 80° C. to about 300° C. or from about 150° C. to about 250° C. Desirable pressures for formation of thin films of silicon and transparent conductive oxides using PECVD can be from about 0.01 Torr to about 5 Torr.

The characteristics of the high frequency power source can affect the quality of thin-films formed from PECVD. Generally, if an appropriate amount of precursor gases are present, increasing the power density can increase the rate of film deposition. However, increasing rate of film deposition can also undesirably increase the temperature of the deposition process. For example, wherein PECVD is used to form a doped semiconducting layer upon an intrinsic semiconducting layer, undesirably high temperatures can lead to diffusion of dopant into the intrinsic layer. For the thin-films of interest herein, desirable power densities can be, for example, from about 0.1 W/cm² to about 6 W/cm². With respect to the RF power frequency, generally, increasing power frequency can reduce the defect density of the deposited film. For thin films of interest herein, desirable power frequencies can be from about 0.05 MHz to about 10 GHz, and in further embodiments from about 0.1 MHz to about 100 MHz. A person of ordinary skill in the art will recognize that additional processing parameter ranges within the explicit ranges above are contemplated and are within the present disclosure.

The selection of the precursor gas composition can be determined with respect the desired composition of the formed thin-film. Both polycrystalline and amorphous Si semiconducting thin-film layers can be formed with a precursor gas comprising SiH₄. Incorporation of PH₃ or BF₃ into the precursor gas can result in formation a n-doped or a p-doped thin-film layer, respectively. Additionally, a precursor gas can generally comprise a forming or reducing gas such as H₂. The gas dilution rate can affect the rate of thin-film formation. For polycrystalline Si thin-films, gas dilution rates of SiH₄ with H₂ can be, for example, no more than about 500 times, or in other words, the molar ratio of H₂ to silane SiH₄ can be no more than about 500 and is generally at least about 5. The selection of amorphous versus polycrystalline elemental silicon formed with PECVD can be selected by adjusting the process conditions. In general, polycrystalline silicon thin-film layers can be formed using a lower discharge power relative to the discharge powers used to form amorphous silicon. Conditions to form amorphous and microcrystalline silicon using PECVD are described in detail in U.S. Pat. No. 6,399,873 to Sano et al., entitled “Stacked Photovoltaic Device,” incorporated herein by reference.

For TCO thin films comprising ZnO, a suitable precursor gas for PECVD deposition can comprise CO₂ and a zinc compound such as dimethyl zinc, diethyl zinc, zinc acetylacetate, and/or zinc acetylacetonate wherein the ratio of CO₂ to the zinc compound is greater than about 3, greater than about 5, or greater than about 10. Incorporation of organometallic aluminum compounds such as Al(CH₃)₃ into the precursor gas can result in formation of a ZnO:Al thin-film layer. In some embodiments, the precursor can comprise from about 0.1% to about 10% oranometallic aluminum. For TCO thin films comprising SnO₂, a suitable precursor can comprise a suitable oxygen source, such as O₂ or CO₂, and a tin precursor compound such as trimethyl tin. The formation of elemental silicon films and TCO layers using PECVD for thin film solar cells is described further in U.S. Pat. No. 6,399,873 to Sano et al., entitled “Stacked Photovoltaic Device,” incorporated herein by reference.

A silicon ink can be applied at a suitable step in the process for the formation of a corresponding polycrystalline silicon film. For the application of the silicon ink to the substrate, suitable coating approaches for the application of the dispersions include, for example, spin coatings, dip coating, spray coating, knife-edge coating, extrusion or the like. Suitable printing techniques include, for example, screen printing, inkjet printing, lithographic printing, gravure printing and the like. The ink can be applied at an appropriate thickness to obtain the ultimate film at a selected thickness. The ink is generally applied at a greater thickness than the ultimate film thickness of the polycrystalline film since the average layer thickness decreases upon drying and further upon sintering. The amount of decrease in average thickness upon processing may depend on the ink formulation. The ink may or may not be patterned on the substrate. In other words, the ink may be substantially uniformly deposited across the substrate. In other embodiments, the inks can be placed at selected locations on the substrate while other locations along the substrate surface may not be covered with ink. Patterning can be used to form a plurality of cells on a single substrate and/or to provide for placement of other elements, such as current collectors, along the uncoated portions of the substrate. As noted above, the inks can be formulated with appropriate properties suitable for the selected coating/printing method.

Generally, the inks can be dried prior to performing sintering to remove solvents. Also, as noted above, further thermal processing can be performed to remove organic components such as through oxidation. The thermal processing prior to sintering can be performed using any convenient heating approach, such as the use of an oven, a heat lamp, convective heating or the like. Appropriate venting can be used to remove vapors from the vicinity of the substrate.

Once the solvent and optional additives are removed, the silicon particles can then be melted to form a cohesive mass of the elemental silicon as a film. The approach used to sinter the silicon particles can be selected to be consistent with the substrate structure to avoid significant damage to the substrate during silicon particle processing. For example, laser sintering, rapid thermal processing, or oven based thermal heating can be used in some embodiments.

However, improved control of the resulting doped substrate as well as energy saving can be obtained through the use of light to melt the silicon particles without generally heating the substrate or only heating the substrate to lower temperatures. Local high temperatures on the order of 1400° C. can be reached to melt the surface layer of the substrate as well as the silicon particles on the substrate. Generally, any intense source selected for absorption by the particles can be used, although excimer lasers or other lasers are a convenient UV source for this purpose. Excimer lasers can be pulsed at 10 to 300 nanoseconds at high fluence to briefly melt a thin layer on the substrate. Longer wavelength light sources such as green lasers or infrared lasers can also be used. Suitable scanners are commercially available to scan a laser beam across a substrate surface, and scanners generally comprise suitable optics to efficiently scan the beam from a fixed laser source. The scan or raster speeds can be set to achieve desired sintering properties, and examples are provided below. In general, the desired laser fluence values and scan rates depend on the laser wavelengths, thickness of the layers as well as the particular compositions. In some embodiments, with respect to laser scanning, it may be desirable to provide two passes, three passes, four passes, five passes or more than five passes of the light beam over the same pattern of the surface to obtain more desirable results. In general, the line width can be adjusted using the optics to select the corresponding light spot size at least within reasonable values.

The silicon particles from the ink can also be sintered using rapid thermal annealing. A rapid thermal anneal can be performed with a heat lamp or block heater, although a heat lamp can be convenient to provide direct heating of the dried ink particles with less heating of the substrate. With rapid thermal annealing, the dried ink is rapidly heated to a desired temperature to sinter the particles, and then the structure is relatively slowly cooled to avoid excessive stress development in the structure. The use of high intensity heat lamps to perform a rapid thermal anneal on semiconductor devices is described in U.S. Pat. No. 5,665,639 to Seppala et al., entitled “Process for Manufacturing a Semiconductor Device Bump Electrode Using a Rapid Thermal Anneal,” incorporated herein by reference.

Thermal and light based fusing of silicon particles is described further in published U.S. Patent Application 2005/0145163A to Matsuki et al., entitled “Composition for Forming Silicon Film and Method for Forming Silicon Film,” incorporated herein by reference. In particular, this reference describes the alternative use of irradiation with a laser or with a flash lamp. Suitable lasers include, for example, a YAG laser or an excimer laser. Noble gas based flash lamps are also described. The heating generally can be performed in a non-oxidizing atmosphere.

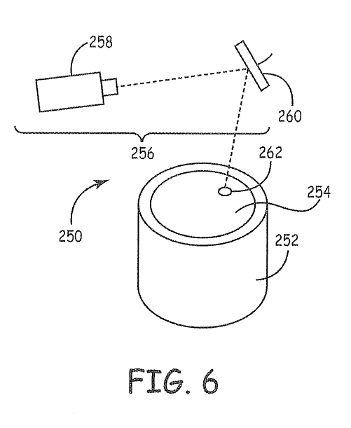

A system for performing silicon ink coating and sintering is shown schematically in FIG. 6. System 250 comprises a spin coater 252 that supports substrate 254. Spin coater 254 can comprise a heater to heat substrate 254 if desired. A laser sintering system 256 comprises a laser light source 258 and suitable optics 260 to scan a laser spot 262 across the substrate as desired.

After all of the layers of the solar cell have been formed, the cell assembly can be completed. For example, a polymer film can be placed over the back of the solar cell for protection from the environment. Also the solar cell can be integrated into a module with a plurality of other cells.

### EXAMPLES

### Example 1

### Dispersions of Si Nanoparticles

This example demonstrates the ability to form well dispersed silicon nanoparticles at high concentrations without surface modification of the particles.

Dispersions have been formed with silicon nanoparticles having different average primary particle sizes. The crystalline silicon particles were formed with high levels of doping as described in Example 2 of copending U.S. provisional patent application Ser. No. 61/359,662 to Chiruvolu et al., entitled “Silicon/Germanium Nanoparticle Inks and Associated Methods,” incorporated herein by reference. Concentrated solutions were formed that are suitable for ink applications, and the solvent is also selected for the particular printing application. For secondary particle size measurements, the solutions were diluted so that reasonable measurements could be made since concentrated solutions scatter too much light to allow secondary particle size measurements.

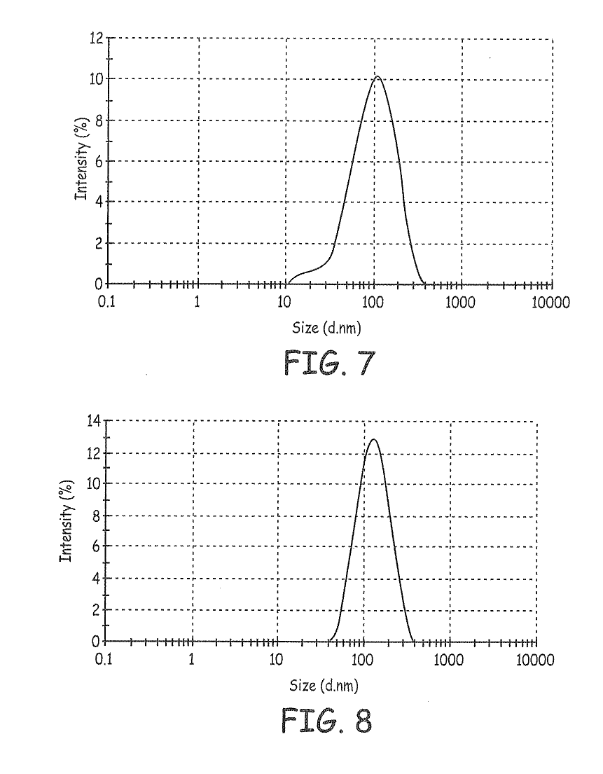

The particles were mixed with the solvent and sonicated to form the dispersion. The dispersions were formed at concentrations of 3-7 weight percent particles. The samples were diluted to 0.4 weight percent particles for the secondary particle size measurements, and the measurements were made using differential light scattering (DLS). Referring to FIGS. 7 and 8, the secondary particle sizes were measured in isopropyl alcohol for particles with average primary particle sizes of 25 nm (FIG. 7) and 9 nm (FIG. 8). The Z-average secondary particle sizes were similar for the two sets of Si particles with the Z-average particles sizes being slightly larger for the particles with about 9 nm average primary particle size. These results suggest greater agglomeration for the particles having a 9 nm average particle diameter. A close examination of the 9 nm particles by transmission electron microscopy yielded a view of more agglomerated non-spherical particles, which is consistent with the secondary particle size measurements.

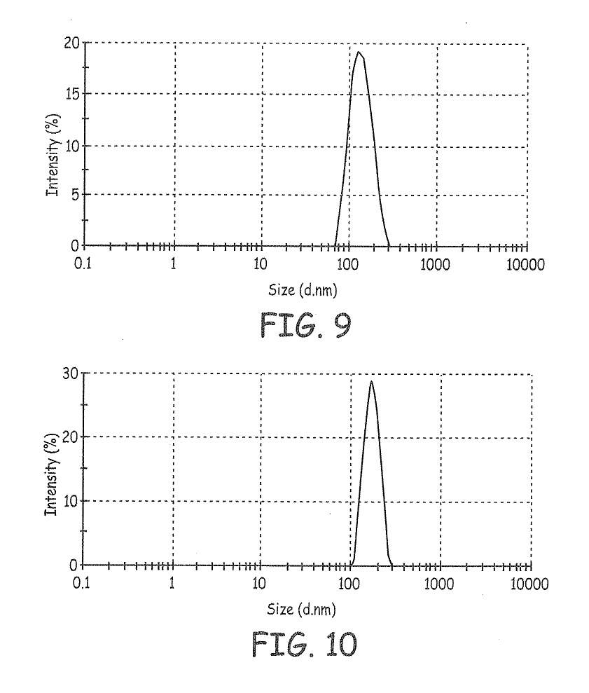

Dispersions were also formed in other solvent systems suitable for other printing approaches. Specifically, a dispersion was formed in a ethylene glycol. The solution was formed at a concentration of silicon particles of 3-7 weight percent. For the measurement of the secondary particle size by DLS, the dispersion was diluted to 0.5 weight percent Si nanoparticles. The DLS results are shown in FIG. 9. Also, a dispersion was formed in a terpineol. Again, the dispersion was diluted to a concentration of 0.5 weight percent particles for measurement of the secondary particle size by DLS as shown in FIG. 10. The secondary particle size measurements for the terpineol based solvent system were similar to the particle size measurements in the ethylene glycol based solvent system.

These secondary particles sizes were suitable for forming inks with good performance for inkjet printing, spin coating and screen printing.

### Example 2

### Viscosity Measurements on Inks

This example demonstrates concentrated suspensions of doped silicon nanoparticles in a solvent suitable for screen printing.

For screen printing, the dispersions are desired to have a greater viscosity and a greater concentration. Various solvent mixtures were tested with respect to viscosity. Dispersions of silicon nanoparticles were formed in solvent mixtures of NPM and PG at various particle concentrations. The undoped silicon nanoparticles had an average primary particle diameter of about 30 nm. Ultrasound was used to facilitate the dispersion. The rheology of the resulting dispersions was studied. Some of the dispersions solidified so that fluid measurements could not be performed. The results are presented in Table 1.

TABLE 1

| | Solvent | | Viscosity | YS | |
|---|---|---|---|---|---|
| Sample | ID | Si wt % | (cP) | (D/cm²) | Rheology |
| 1 | 1 | 17.0 | 16.88 | 0 | N |
| 2 | 2 | 15.4 | 12.99 | 4.3 | NN |
| 3 | 3 | 15.3 | 31.70 | 6.3 | NN |
| 4 | 4 | 15.5 | — | ∞ | — |
| 5 | 5 | 14.4 | — | ∞ | — |
| 6 | 6 | 13.2 | — | ∞ | — |
| 7 | 1 | 14.1 | 5.83 | 3.4 | NN |
| 8 | 2 | 16.1 | 10.03 | 0.0 | N |
| 9 | 3 | 14.6 | 10.58 | 0.0 | N |
| 10 | 4 | 14.1 | 22.89 | 3.3 | NN |
| 11 | 5 | 14.8 | — | ∞ | — |
| 12 | 6 | 13.1 | — | ∞ | — |
| 13 | 1 | 11.7 | 1.81 | 0.0 | N |
| 14 | 2 | 14.0 | 11.51 | 0.0 | N |
| 15 | 3 | 11.4 | 7.29 | 0.0 | N |
| 16 | 4 | 10.9 | 13.60 | 1.7 | NN |
| 17 | 5 | 12.3 | 15.18 | 2.3 | NN |
| 18 | 6 | 11.9 | — | ∞ | — |

In Table 1, YS refers to yield stress in dynes per square centimeter. Yield stress is proportional to a force exerted to initiate flow of the non-Newtonian fluid in a tube. The shear stresses as a function of the shear rates were fit to a straight line by least squares, and the slope corresponds to the viscosity and the y-intercept corresponds to the yield stress. By increasing the particle concentration in a good dispersing solvent, non-Newtonian properties can be obtained that are expected for proper inkjet ink. From the results above, yield stress increased with an increase in Si particle concentration and an increase in propylene glycol concentration.

The solvents listed in Table 1 were various blends of propylene glycol and N-methylpyrrolidone (NMP). All of the blends had Newtonian rheology. The compositions and viscosities for these solvent blends are summarized in TABLE 2.

TABLE 2

| Solvent | | Viscosity |
|---|---|---|
| ID | Wt % PG | (cP) |
| 1 | 12.6 | 2.47 |
| 2 | 25.1 | 3.59 |
| 3 | 37.1 | 5.06 |
| 4 | 50.0 | 7.51 |
| 5 | 62.6 | 11.33 |
| 6 | 74.8 | 16.64 |

The dispersions that did not solidify were also diluted to an approximate 1 weight percent concentration. Light scattering was used to evaluate the properties of the dispersion based on the diluted samples. The results are summarized in Table 3. No measurements were possible for the samples that solidified. Samples 10 and 17 formed gels, but measurements were still possible for these samples.

TABLE 3

| | Z-average | Distribution | |
|---|---|---|---|
| Sample | (nm) | Peak (nm) | PDI |
| 1 | 273 | 331 | 0.24 |
| 2 | 99 | 123 | 0.22 |
| 3 | 57 | 71 | 0.22 |
| 7 | 298 | 390 | 0.23 |
| 8 | 106 | 139 | 0.22 |
| 9 | 80 | 102 | 0.22 |
| 10 | 54 | 69 | 0.22 |
| 13 | 309 | 404 | 0.24 |
| 14 | 103 | 123 | 0.25 |
| 15 | 75 | 95 | 0.21 |
| 16 | 60 | 75 | 0.19 |
| 17 | 44 | 57 | 0.23 |

As seen in Table 3, the dispersion size decreased with increasing amounts of PG in the solvent blend.

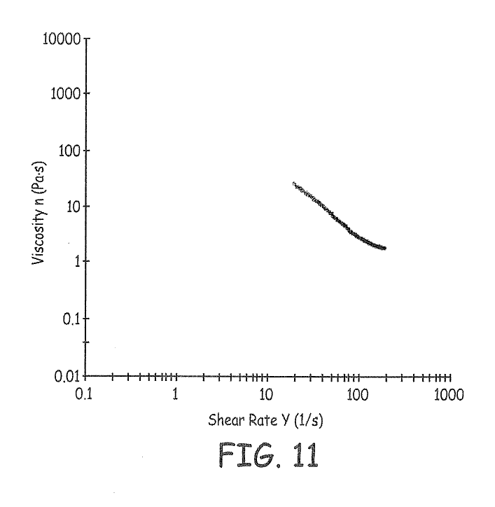

For non-Newtonian fluids, the viscosity is a function of the shear rate. A silicon particle paste was prepared with silicon nanoparticles at a concentration of about 10-15 weight percent in an alcohol based solvent. A plot of viscosity as a function of shear rate is plotted in FIG. 11. The viscosity of this paste is on the order of 10 Pa·s (10,000 cP). The viscosity varies significant over the plotted range of shear rate from about 20 (1/s) to about 200 (1/s).

### Example 3

### Formation and Structural Characterization of Polycrystalline Thin-Films From Silicon Inks

This example demonstrates the formation of polycrystalline thin-films from silicon inks and the structural characterization of such films.

A polycrystalline thin-film was formed by first depositing a Si ink onto a substrate and subsequently sintering the coated substrate. The Si ink was formed essentially as described in Example 1 and comprised undoped Si nanoparticles with an average primary particle diameter from 25-35 nm dispersed in an alcohol based solvent. Spin coating was then used to deposit the Si ink in a coating from about 150-250 nm average thickness onto a silica glass wafer. The coated wafer was subsequently soft-baked in an oven at roughly 85° C. to dry the ink prior to laser sintering. Laser sintering was performed with a pulsed excimer laser to sinter the silicon nanoparticles into a polycrystalline thin film.

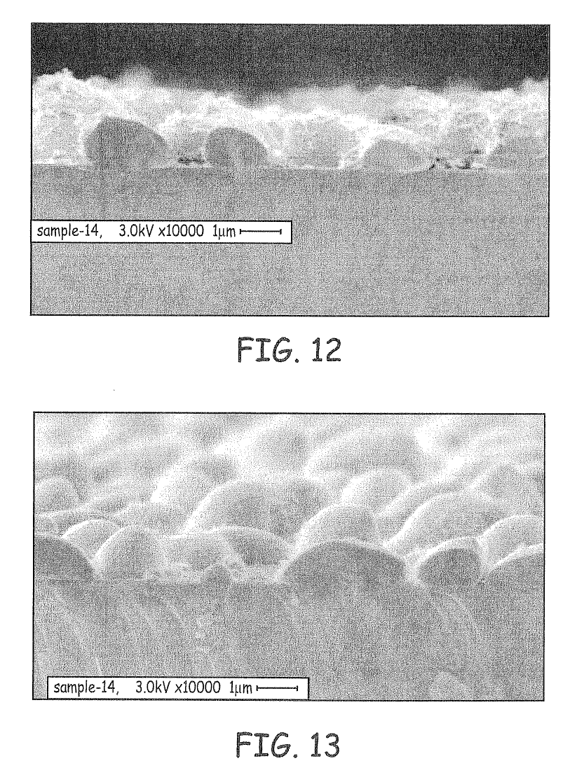

The polycrystalline thin-film comprised micron-sized, single crystal Si structures. FIG. 12 is a SEM image of a cross section of the polycrystalline layer after sintering. FIG. 12 reveals that the polycrystalline layer comprises micron-sized crystallites, which adhered well to the underlying glass substrate. The polycrystalline material had the visual appearance of frizzy contours on the surface of the micron-sized particles. The fuzzy appearing composition on the particles was substantially removed using an alkaline isopropyl alcohol (“IPA”) solution. FIG. 13 is an SEM image of the polycrystalline thin-film after treatment with the IPA solution.

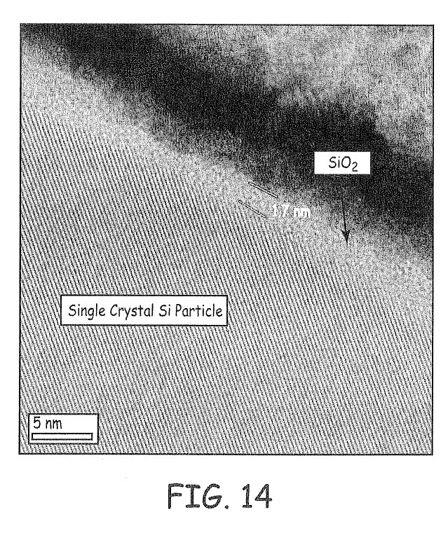

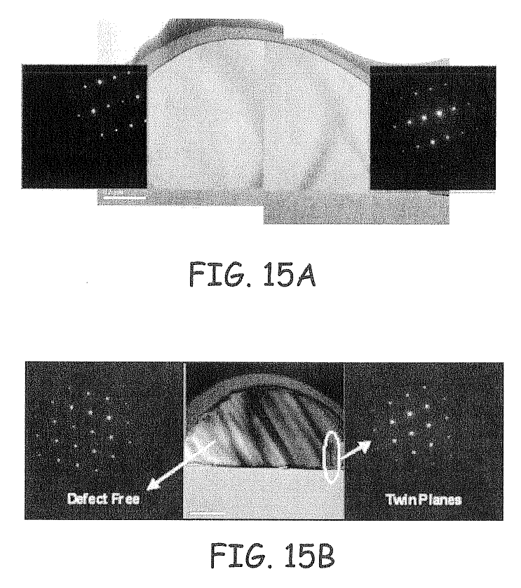

The micron-sized particles formed during sintering comprised single crystal silicon. FIG. 14 is a high resolution TEM image of a cross section of a micron-sized Si crystallite revealing the single crystal structure. FIGS. 15a and 15b are electron diffraction patterns confirming that bulk material of the micron-sized Si particle is single crystal. Diffraction patterns generated from the bulk region of the micron-sized Si particle show a single crystal structure (FIG. 15a and FIG. 15b (left panel)). Twins and twist boundaries were found near the edges of the crystal (FIG. 15b (right panel)).

Furthermore, although Si nanoparticles in the pre-sintered ink contained, on average, 2% atomic oxygen, the single crystal Si particles formed during laser sintering did not have any detectable oxygen content within the bulk composition. FIG. 14 reveals that the single crystal Si particles have a 1.7 nanometer layer of SiO₂. This oxide layer was removed using a buffered oxide etch, and energy dispersive X-ray spectroscopy (EDS) was used to determine the oxygen content of laser sintered ink. Sample EDS measurements were taken in the glass substrate immediately below the single crystal Si particles, within the interstitial regions between single crystal Si particles, and within the single crystal Si particles. FIG. 16 is an SEM image of a cross-section of fused single crystal Si particles and is used as a map of representative sampling regions. As measured by EDS analysis, samples areas represented by region 1 had an oxygen to silicon ratio of 2:1, characteristic of the SiO₂ substrate. The interstitial regions had measured oxygen to silicon ratios of 1:9 and 2:3 for representative regions 2 and 3, respectively. However, within the single crystal Si particles, EDS did not detect any oxygen content (representative region 4), suggesting that oxygen was driven out of the bulk composition of the Si nanoparticles during sintering.

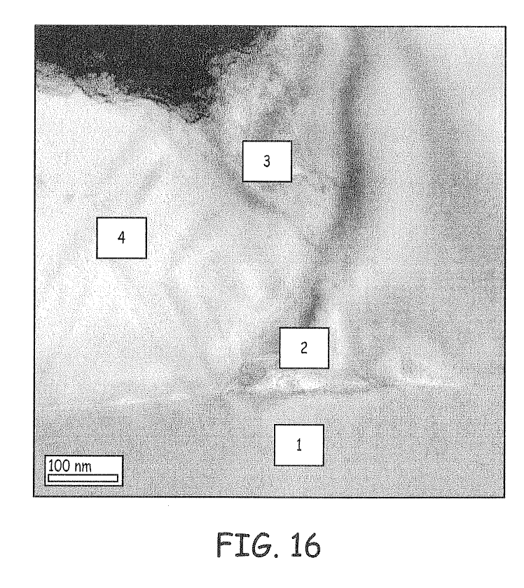

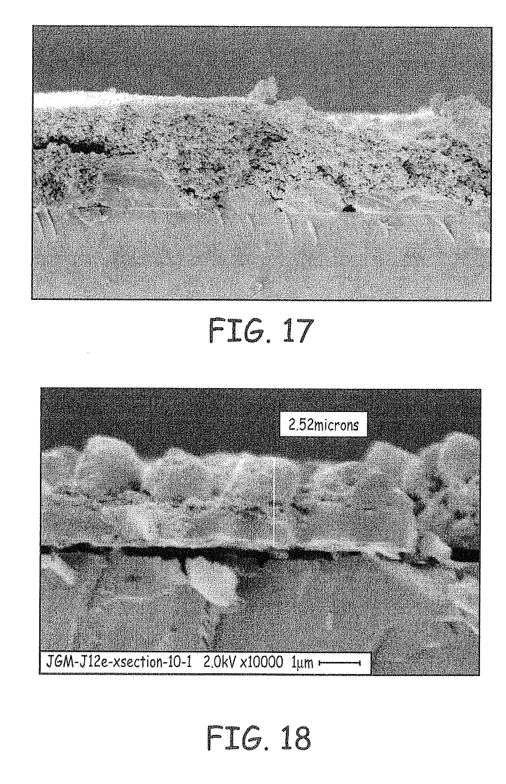

The uniformity of the polycrystalline thin-film was improved by depositing a second Si ink on the initial polycrystalline thin-film and subsequently sintering the second deposited Si ink. The second Si ink was essentially the same composition as described above in this Example. The second Si ink was spin coated onto the polycrystalline thin-film and subsequently soft-baked in an oven to dry the ink. FIG. 17 is an SEM image of a cross section polycrystalline thin film coated with the second Si ink after the soft bake and prior to performing the second sintering step. The coated thin-film was then laser sintered with a pulsed excimer laser. FIG. 18 is an SEM image of a cross section of the polycrystalline thin-film after sintering the second silicon ink. A visual evaluation of the micrograph of the film after sintering the second ink deposit shows an improved uniformity.

### Example 4

### Formation of a Polycrystalline Thin-Film on a Transparent Conductive Electrode

This example demonstrates the formation of a polycrystalline thin-film on a substrate comprising a transparent conductive oxide (TCO) electrode.

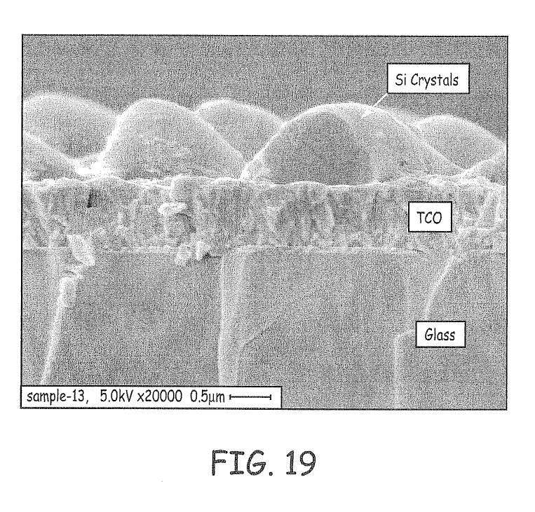

A polycrystalline thin-film was formed on the TCO layer by first depositing a Si ink onto the TCO layer and subsequently sintering the deposited Si ink. The Si ink was formed essentially identically to the Si ink described in Example 3. Spin coating was then used to deposit the Si ink with an average layer thickness from about 150 to 250 nm onto the TCO coated wafer. The deposited Si ink was subsequently soft-baked in an oven to dry the ink prior to laser sintering. Laser sintering was performed with a pulsed excimer laser. FIG. 19 is a SEM image of a cross section of the polycrystalline thin-film formed on the TCO coated wafer. Good adhesion and contact was obtained between the polycrystalline thin-film and the TCO layer.

### Example 5

### Surface Coverage of Polycrystalline Thin-Films

This example demonstrates the effects of Si ink composition and laser sintering parameters on the surface coverage of laser sintered thin films.

Eight samples of polycrystalline silicon films were formed. The samples differed in ink composition, deposition thickness, and/or laser sintering parameters. For each sample, the polycrystalline thin-film was formed by first depositing a Si ink onto a substrate and subsequently sintering the coated substrate. The Si inks were formed essentially as described in Example 1 and comprised undoped Si nanoparticles dispersed in an alcohol based solvent. The average primary particle diameter of the Si nanoparticles was 7 nm-35 nm, and values for particular samples are provided in Table 4. Spin coating was then used to deposit the Si ink onto a wafer having a SiO₂ layer on the surface with an average ink layer thickness of 150 nm-250 nm. The coated silicon wafer was subsequently soft-baked in an oven at roughly 85° C. to dry the ink prior to laser sintering. Laser sintering was performed using an excimer laser (Coherent LP210) with a center wavelength of 308 nm and a pulse width of 20 ns (full width at half maximum (FWHM)). The laser had a fluence of 40-350 mJ/cm² and a spot size of 8.5×7.5 mm². The laser was operated at 20 Hz with 1 pulse-20 pulses per laser spot. Details of the Si ink composition and laser sintering parameters for each sample are shown in Table 5. In this Example, samples will be referred to by their sample number as shown in Table 4.

TABLE 4

| | Average Size of | Si Ink | | |
|---|---|---|---|---|
| | Si Nanoparticles | Deposition | | |
| Sample | in Si Ink | Thickness | Laser Fluence | |
| No. | (mu) | (nm) | (mJ/cm²) | Pulses per Spot |
| 1 | 7 | 200 | 160 | 20 |
| 2 | 35 | 150 | 160 | 20 |
| 3 | 35 | 200 | 117 | 1 |
| 4 | 35 | 200 | 117 | 20 |
| 5 | 35 | 250 | 70 | 20 |
| 6 | 35 | 250 | 117 | 20 |
| 7 | 7 | — | 40/7/200 | 10/5/2 |
| 8 | 7 | — | 200 | 20 |

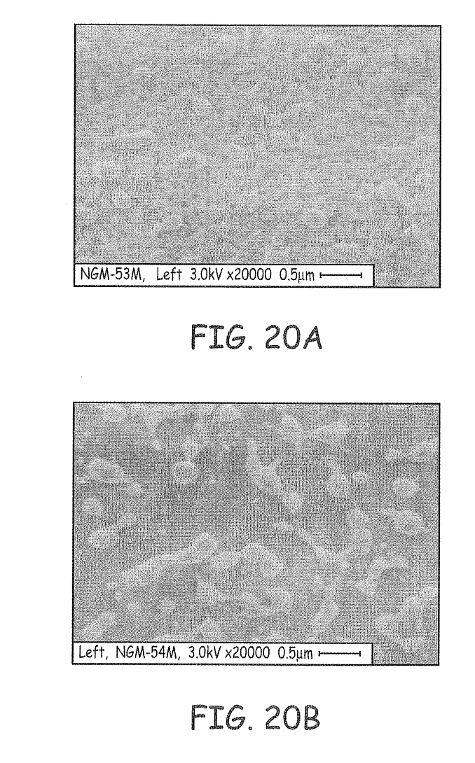

Variation in Si ink composition was seen to have a substantial effect on the surface coverage of the sintered films. In particular, it was generally found that thin-films sintered from Si inks comprising smaller Si nanoparticles had improved surface coverage of the Underlying layer. FIGS. 20a and 20b are SEM images of samples 1 and 2, respectively. Sample 1 was formed form a Si ink comprising Si nanoparticles with an average size of 7 nm. Sample 2 was formed from a Si ink comprising Si nanoparticles with an average size of 35 nm. Sample 1 is seen to have improved surface coverage of the TCO layer relative to Sample 2. In particular, measurements of surface coverage revealed that sample 1 has a surface coverage of 92% and sample 2 has a surface coverage of 35%.

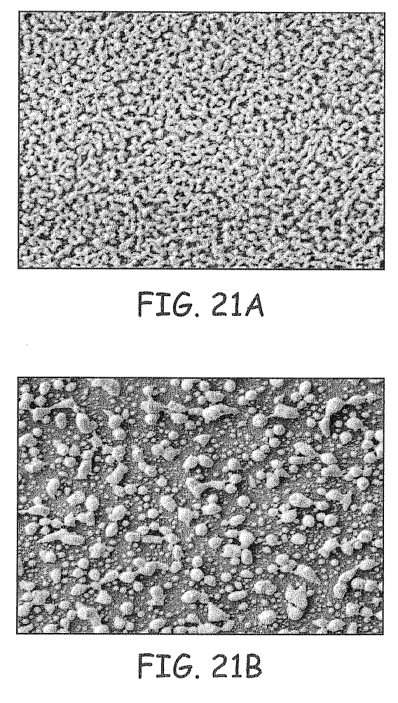

Variation in laser parameters during sintering was also found to have a substantial effect on surface coverage of the sintered films. In particular, it was generally observed that fewer pulses per spot during scanning result in improved surface coverage of the underlying layer. FIGS. 21a and 21b are SEM images of samples 3 and 4, respectively, and show the effect of the variation of the number of laser pulses used to sinter deposited Si nanoparticles. Sample 3 was formed by laser sintering wherein a single pulse was delivered at each laser spot during scanning. Sample 4 was formed by laser sintering wherein 20 pulses were delivered at each laser spot during scanning. Sample 3 is seen to have improved surface coverage of the substrate oxide layer relative to sample 4.

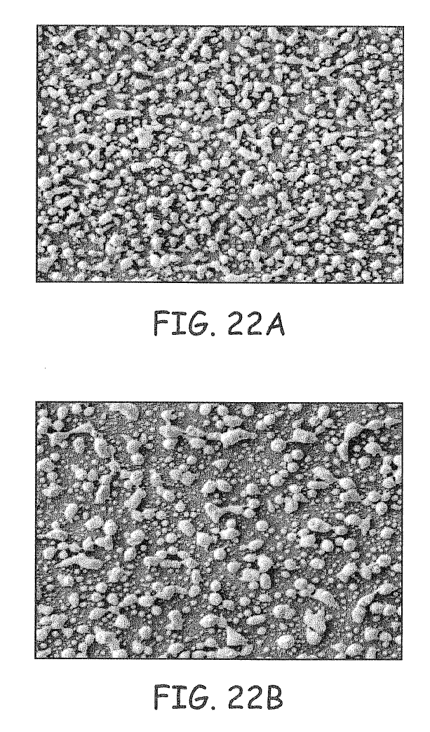

Also, it was generally seen that using a lower laser fluence improved surface coverage of the underlying layer. FIGS. 22a and 22b are SEM images of samples 5 and 6, respectively, and the effect of the variation of laser fluence during sintering can be observed form these figures. Sample 5 was formed by laser sintering using a laser fluence of 70 mJ/cm². Sample 6 was formed by laser sintering using a laser fluence of 117 mJ/cm². Sample 5 is seen to have improved surface coverage of the substrate oxide layer relative to sample 6.

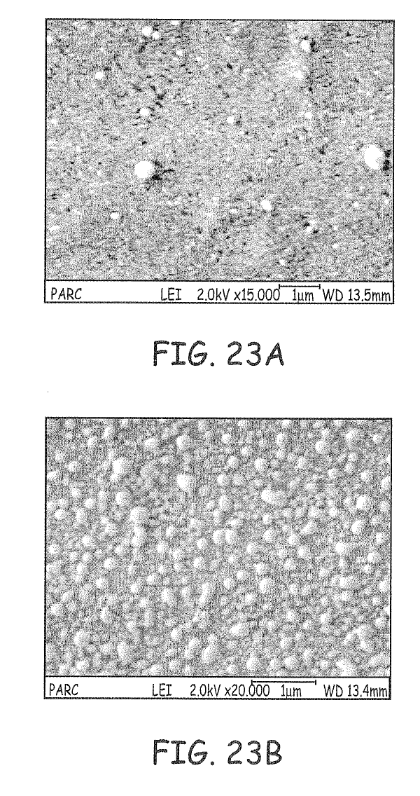

Moreover a graded fluence sintering process was also seen to improved surface coverage of the underlying substrate oxide layer. FIGS. 23a and 23b are SEM images of samples 7 and 8, respectively, and show the effect of a graded fluence sintering process. Sample 7 was prepared by laser sintering comprising three sintering steps. In particular, sample 7 was initially sinitered using a laser fluence of 40 mJ/cm² with 10 pulses delivered at each laser spot. Sample 7 was then sintered again using a laser fluence of 70 mJ/cm² with 5 pulses delivered at each laser spot. Finally, sintering was completed by using a laser fluence of 200 mJ/cm² with 2 pulses delivered at each laser spot. In contrast, sample 8 was prepared with a single sintering step using a laser fluence of 200 mJ/cm² with 20 pulses delivered at each laser spot. Sample 7 is seen to have improved surface coverage relative to sample 8.

### Example 6

### Laser Sintered Silicon Ink: Electrical Conductivity

In this example, phosphorous-doped silicon nanoparticles were dispersed in isopropyl alcohol. The resulting inks were spin coated onto a p-type silicon wafer. The solvent was dried.

Then, an infrared laser was scanned to fuse the silicon at selected locations along the substrate. Silicon inks with different phosphorous dopant amounts were printed using notation n+ for 0.2 to 0.4 atomic %, n++ for 2 to 4 atomic % and n+++ for 7-8 atomic percent P.

Several silicon inks were sintered using an infrared laser. Specifically, a thicker layer 0.5-1.0 microns) was formed with silicon particles doped at a lower of phosphorous, and thinner layers (0.25-0.5 micron) were formed with Si particles doped at a greater level of phosphorous. The processing had significant tradeoffs. More intense sintering with the laser can result in damage to the underlying substrate. The printed was done onto a cleaned surface of a p-type silicon wafer having a 200 micron thickness and a 1-5 ohm-cm resistance. The sintered Si ink layer passed a tape peel test. The lowest measured sheet resistances for the different particle doping levels were as follows: n+++ 6-10 Ω/square, n++ 10-30 Ω/square and n+ 30-40 Ω/square. The sintered Si ink layer had a conductivity that is generally 1.5-3 times lower than that of bulk Si at a given dopant level.

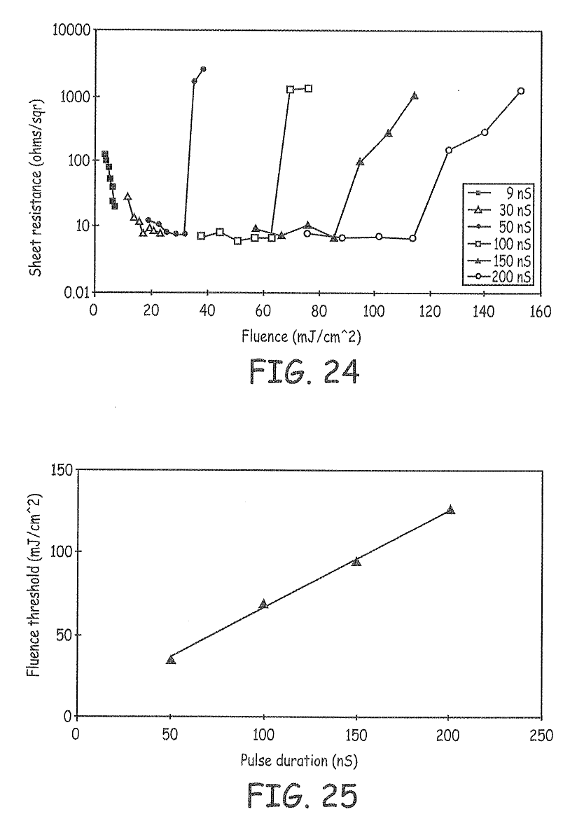

FIG. 24 is a plot of sheet resistance as a function of laser fluence for an n++ Si ink layer with a 500 nm thickness for 6 different laser pulse widths. The graph in FIG. 24 shows that the sheet resistance decreased with increasing fluence initially, and then remained relatively constant over a range of fluence. As fluence increased to the threshold value, sheet resistance increased abruptly, indicating laser damage. FIG. 25 shows a linear relationship between the fluence threshold and pulse duration.

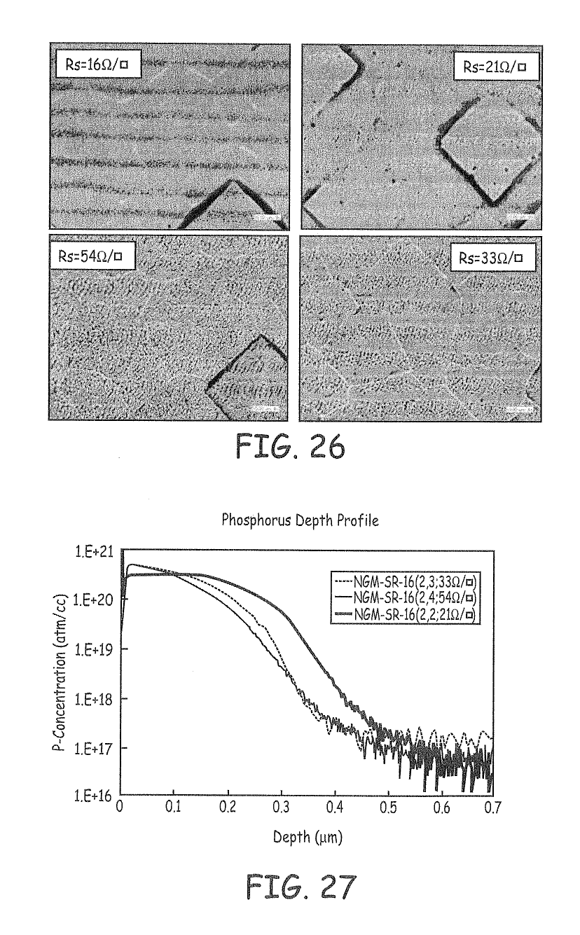

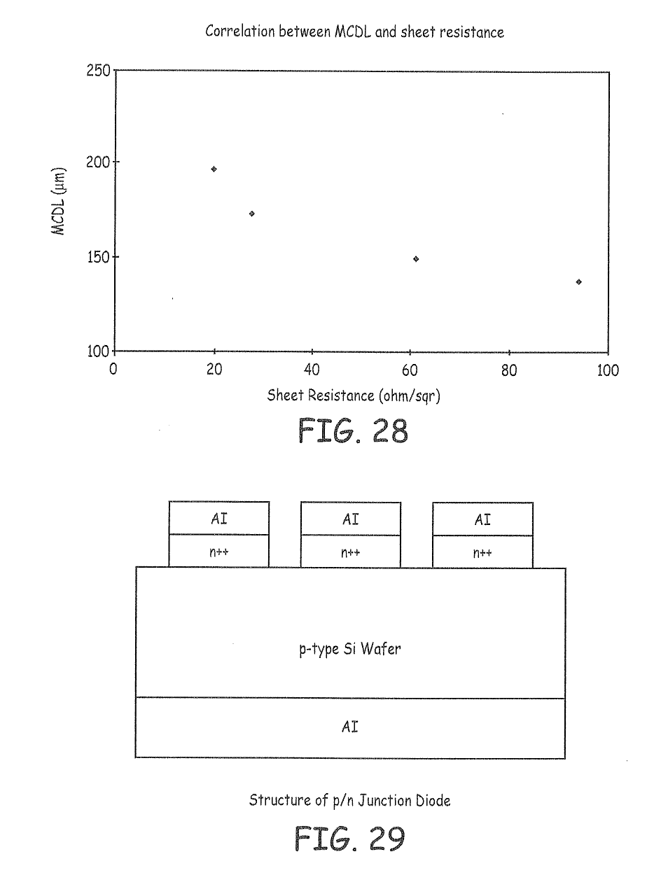

The sheet resistance seemed consistent with surface morphology. Optical micrograph pictures are shown for samples with different sheet resistances in FIG. 26. Samples with lower sheet resistances had smoother surfaces. The dopant profile was measured using Secondary Ion Mass Spectrometry (SIMS) to evaluate the elemental composition along with sputtering or other etching to sample different depths from the surface. With a reasonable cutoff based on concentration, the depth of phosphorous was essentially 0.32 microns for a sample with a sheet resistance of 33 Ohm/(square). The depth profile is shown in FIG. 27. Sheets with lower resistance tended to have deeper penetration of P within the layer. The minority carrier diffusion length (MCDL) increased with a decrease in sheet resistance. A plot of MCDL as a function of sheet resistance is found in FIG. 28.

A schematic diagram of the p-n junctions is shown in FIG. 29 in which the n-doped layer of the junction is formed with a silicon ink. P-type Si wafers used to fabricate p/n junctions diodes were 100 mm in diameter, 200 microns thick and 1-5 ohm-cm in resistivity. The wafers were etched in 25% KOH at 80° C. for 15 minutes to remove saw damage and then dipped in 2% HF for a few seconds to remove surface oxide. Inks formed from phosphorous doped Si particles were used to form p/n junction diodes. The particles for these inks had BET surface area based average particle sizes of 25 nm. One set of particles had a doping of 2×10²⁰ atoms of P per cm³ and another set of particles had a doping of 1.5×10²¹ atoms of P per cm³. The particles were dispersed at 5 weight percent in isopropyl alcohol. The inks were applied by spin coating onto the entire surface of the wafer. The inks layer was dried at 85° C. in a glove box. The dried layers had a thickness from 0.250 to 1 micron.

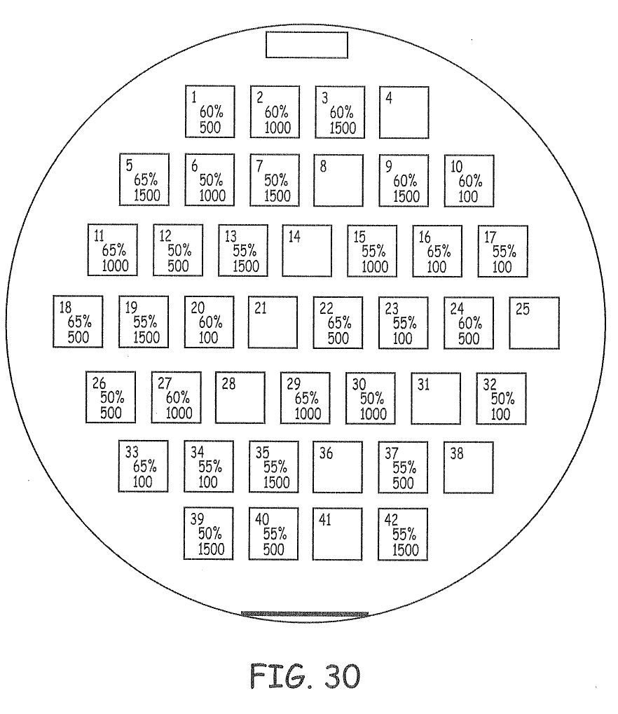

An infrared fiber laser was used to irradiate 42 1 cm×1 cm squares across the wafer as shown in FIG. 30 where the numbers in each square are the sequential cell number, the percentage of the laser power and scanning speed in mm/s. The laser was operated at a constant repetition rate of 500 kHz and a 16 W average power. After irradiation with the laser, the wafer was then immersed in 1% KOH in IPA till bubbles cease, about 2-3 minutes, at ambient temperature to removed “green” or unsintered Si ink coating outside of the illuminated squares. Sheet resistances of the irradiated squares were in the range from 10 to ˜700 ohms/sqr. Aluminum was deposited on the squares and the backside of the wafer to complete the diodes. Each square was a phi junction diode. The best performing diode was from cell number 10, which was made from an ink of Si particles with phosphorous at 2×10²⁰ atm/cm³ and an ink layer thickness of 500 nm. The sheet resistance of cell number 10 measured before Al deposition was 56.7 ohm/sqr.

### Example 7

### Thermal Curing of Si Inks

This example demonstrates the thermal sintering of the printed silicon nanoparticles to obtain reasonable levels of electrical conductivity.

Samples of silicon inks were applied to single crystal silicon wafers by spin coating.

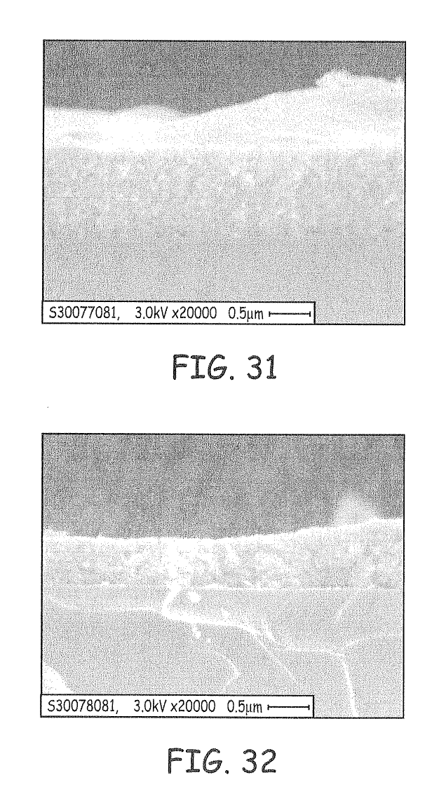

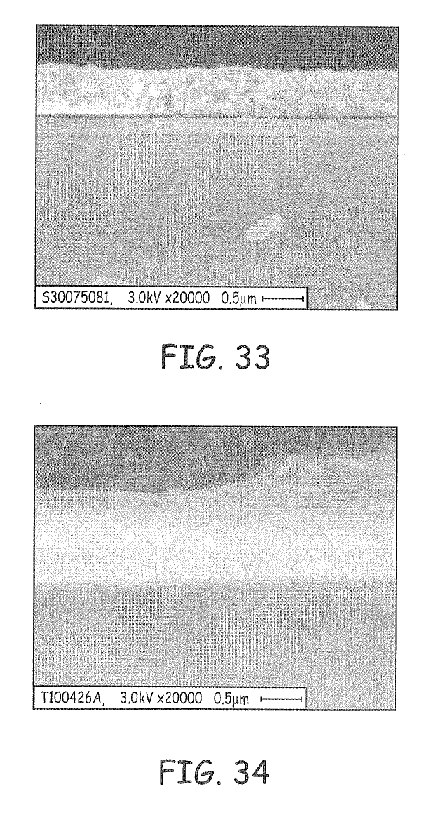

Specifically, the respective inks had crystalline silicon particles with average primary particle sizes of 7 nm, 9 nm or 25 nm, and the silicon particles were doped with phosphorous at a level of 2 to 4 atomic %. The particle coated films had thicknesses form about 0.5 microns to about 1 micron. SEM micrographs of cross sections of the coated wafers are shown in FIGS. 31-33.

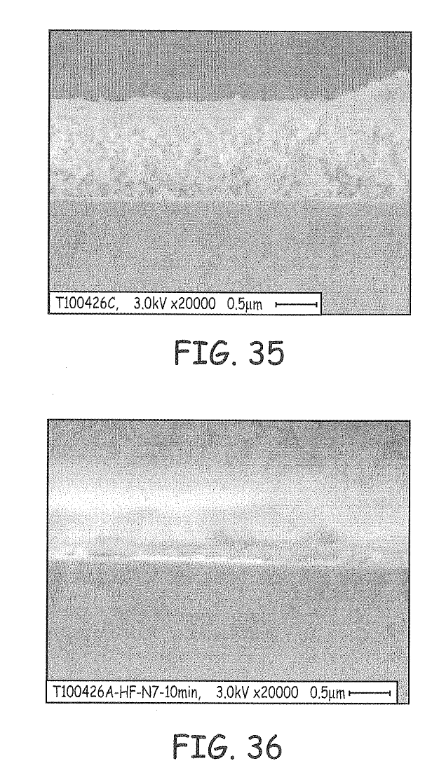

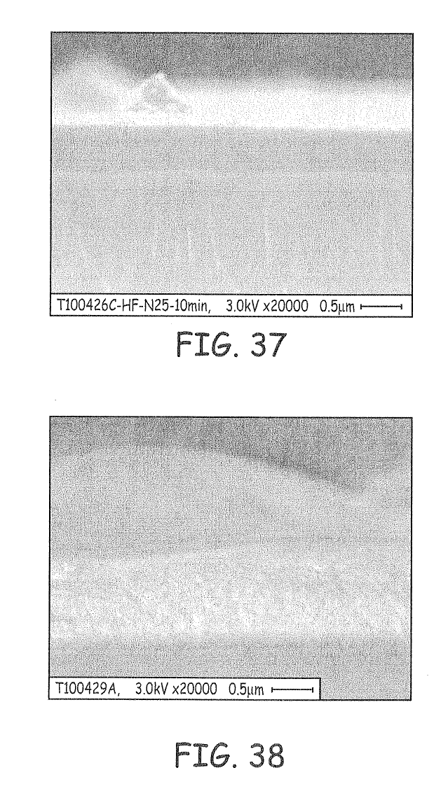

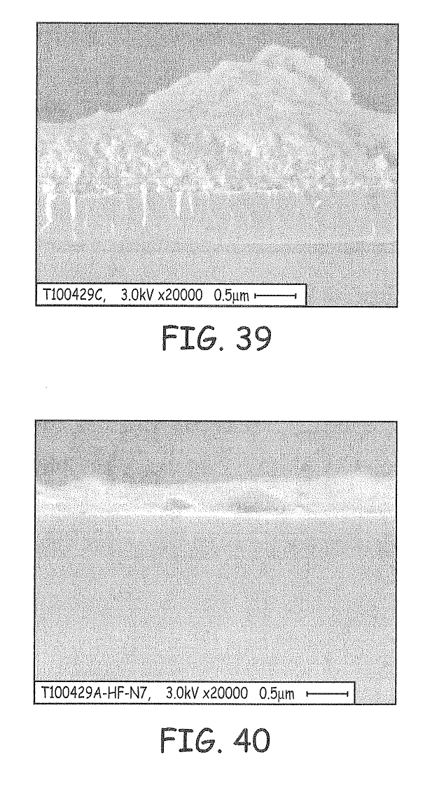

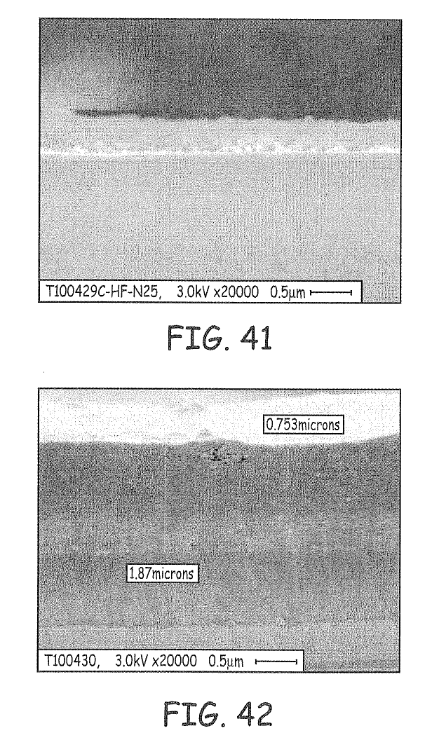

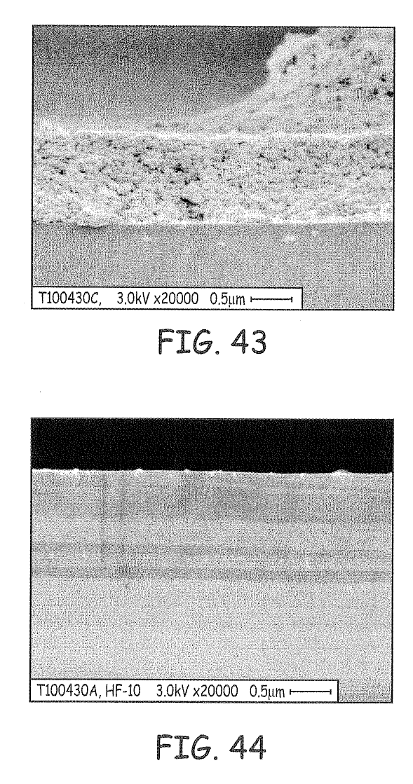

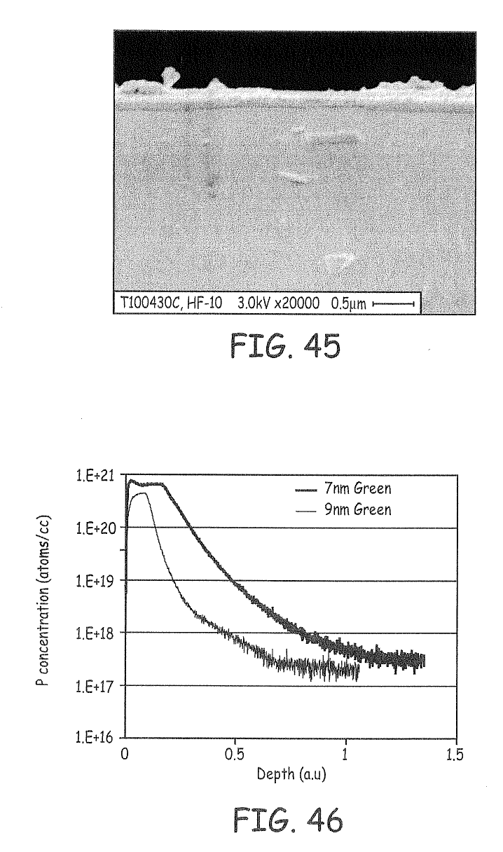

The coated wafers were densified in a furnace at 1050° C. for 60 minutes at various gas flows. All of the densified samples passed a tape test, which supports a conclusion that the samples were densified. Some material were removed with an HF etch suggesting some silicon oxide may be removed. Samples with initial smaller primary particle size for the silicon particles had a larger proportion of material removed with the HF etch. Based on examinations by scanning electron microscopy, samples that were printed with smaller primary particle size silicon became more densified upon heating in the furnace. SEM micrographs of cross sections of densified samples are shown in FIGS. 34 (7 nm primary particles) and 35 (25 nm primary particles) for samples that were heated in a flow of Ar/H₂ gas. FIGS. 36 and 37 shown the samples from FIGS. 34 and 35 after an HF etch. Samples that were densified in a flow of Ar/H₂ gas had the lowest sheet resistance. For samples that were densified under a flow of nitrogen gas, SEM micrographs of cross sections of densified samples are shown in FIGS. 38 (7 nm primary particles) and 39 (25 nm primary particles). FIGS. 40 and 41 shown the samples from FIGS. 38 and 39 after an HF etch. For samples that were densified under a flow of compressed air, SEM micrographs of cross sections of densified samples are shown in FIGS. 42 (7 nm primary particles) and 43 (25 nm primary particles). FIGS. 44 and 45 shown the samples from FIGS. 42 and 43 after an HF etch.

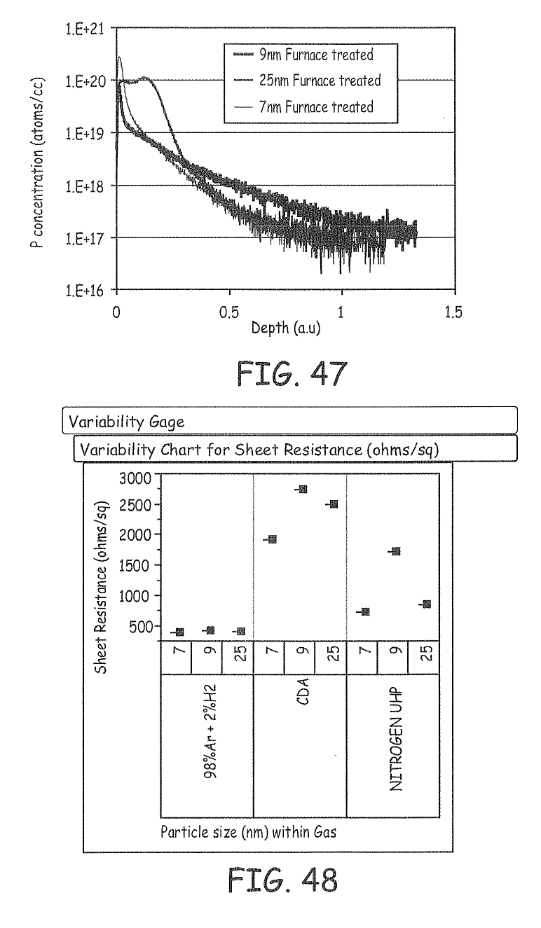

The dopant profile was measured using Secondary Ion Mass Spectrometry (SIMS) to evaluate the elemental composition along with sputtering or other etching to sample different depths from the surface. The dopant profile results for two samples prior to densifying the samples in the furnace are plotted in FIG. 46. Similarly, the dopant profile results for three samples after densifying the samples in the furnace are shown in FIG. 47. The dopant concentration in the densified films is considerably lower than in the green, i.e., undensified, layers.

Electrical measurements were performed for samples after densification in the furnace and after a 10 minute HF etch. The sheet resistance measurements are presented in FIG. 48 for 9 samples. As noted above, the lowest sheet resistance measurements were obtained for samples densified under Ar/H₂ gas flow.

The specific embodiments above are intended to be illustrative and not limiting. Additional embodiments are within the broad concepts described herein. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What is claimed is:

1. A method for forming a thin film solar cell structure comprising:
depositing a layer of ink comprising elemental silicon particles, wherein the ink has a z-average secondary particle size of no more than about 250 nm as determined by dynamic light scattering on an ink sample diluted to 0.4 weight percent if initially having a greater concentration; and
sintering the elemental silicon particles to form a polycrystalline layer as an element of a p-n junction diode structure wherein the overall the structure comprises a p-doped elemental silicon layer and an n-doped elemental silicon layer.

2. The method of claim 1 wherein the depositing of the ink comprises spin coating.

3. The method of claim 1 wherein the depositing of the ink comprises screen printing.

4. The method of claim 1 wherein the ink comprises silicon particles having an average primary particle diameter of no more than about 75 nm.

5. The method of claim 1 wherein the ink has a z-average secondary particle size of no more than about 250 nm.

6. The method of claim 1 wherein the silicon particles have a dopant level of no more than about 25 ppm.

7. The method of claim 1 wherein the silicon particles comprise P, As, Sb or a combination thereof as a dopant and have a dopant level from about 0.01 atomic percent to about 15 atomic percent.

8. The method of claim 1 wherein the silicon particles comprise B, Al, Ga, In or a combination thereof as a dopant and have a dopant level from about 0.1 atomic percent to about 15 atomic percent.

9. The method of claim 1 wherein the sintering is performed in an oven.

10. The method of claim 1 wherein the sintering is performed with a laser directed at the deposited silicon.

11. The method of claim 1 wherein the polycrystalline layer forms an intrinsic layer of the cell, and further comprising depositing an amorphous intrinsic silicon layer along the surface of the polycrystalline layer.

12. The method of claim 11 further comprising depositing an amorphous doped layer having a dopant concentration from about 0.05 atomic percent to about 35 atomic percent on the amorphous intrinsic layer and applying a current collector positioned to collect current from the amorphous doped layer.

13. A thin film solar cell comprising a composite layer having a composite of polycrystalline silicon and amorphous silicon with a textured interface between domains of the polycrystalline silicon and amorphous silicon that on average form adjacent layers, wherein the overall structure comprises a p-doped elemental silicon layer and an n-doped elemental silicon layer forming a diode junction and wherein the texture reflects the crystallite size of the polycrystalline material.

14. The thin film solar cell structure of claim 13 wherein the polycrystalline layer is an intrinsic layer having a doping level of no more than about 25 ppm and a location between the p-doped elemental silicon layer and the n-doped elemental silicon layer.

15. The thin film solar cell of claim 13 wherein the polycrystalline layer has an average thickness from about 200 nm to about 10 microns.

16. The thin film solar cell of claim 13 wherein the p-doped elemental silicon layer and/or the n-doped elemental silicon layer are also polycrystalline.

17. The thin film solar cell of claim 13 wherein one of the p-doped element silicon layer is polycrystalline and the n-doped elemental silicon layer is amorphous.

18. The thin film solar cell of claim 13 wherein one of the p-doped element silicon layer is amorphous and the n-doped elemental silicon layer is amorphous.

19. The thin film solar cell of claim 13 further comprising a second diode junction comprising an amorphous elemental silicon n-doped layer, an amorphous element p-doped layer and an amorphous intrinsic layer between the n-doped layer and the p-doped layer.

20. The thin film solar cell of claim 13 wherein the n-doped layer has a dopant level from about 0.05 atomic percent to about 35 atomic percent and the p-doped layer has a dopant level from about 0.05 atomic percent to about 35 atomic percent.

21. The thin film solar cell of claim 13 wherein the composite layer comprises from about 0.1 weight percent to about 70 weight percent amorphous silicon.

22. The thin film solar cell of claim 13 wherein the composite layer comprises from about 1 weight percent to about 20 weight percent amorphous silicon.

23. The thin film solar cell of claim 13 wherein the composite layer comprises from about 0.1 to about 40 atomic percent hydrogen.
